(19) United States
(12) Patent Application Publication
(10) Pub. No.: US 2025/0314970 A1
(43) Pub. Date: Oct. 9, 2025

(54) OVERCOAT COMPOSITION AND PATTERNING METHODS

(71) Applicants: Tokyo Electron Limited, Tokyo (JP); Geminatio, Inc., Schenectady, NY (US)

(72) Inventors: Phillip D. Hustad, Schenectady, NY (US); Jordan B. Greenough, Schenectady, NY (US); Max J. Klemes, Schenectady, NY (US)

(21) Appl. No.: 19/097,630

(22) Filed: Apr. 1, 2025

Related U.S. Application Data
(60) Provisional application No. 63/631,164, filed on Apr. 8, 2024.

(51) Int. Cl. G03F 7/11; C09D 7/63; G03F 7/00; G03F 7/004; G03F 7/09; G03F 7/095; G03F 7/38; H01L 21/308

(52) U.S. Cl. CPC G03F 7/11; C09D 7/63; G03F 7/0035; G03F 7/0045; G03F 7/094; G03F 7/095; G03F 7/38; H01L 21/3081

(57) ABSTRACT

An overcoat composition includes a polymer, a fluorine-free acid generator, a base quencher, and an organic solvent. The fluorine-free acid generator includes a five-membered aromatic ring substituted with one or more electron-withdrawing groups.

### CROSS-REFERENCE TO RELATED APPLICATIONS

This application claims the benefit of U.S. Provisional Application No. 63/631,164, filed on Apr. 8, 2024, titled “Narrow Line Cut Masking Process,” which application is hereby incorporated herein by reference.

### TECHNICAL FIELD

The present invention relates generally to semiconductor manufacturing, and, in particular embodiments, to an overcoat composition and methods of patterning substrates.

### BACKGROUND

Semiconductor device fabrication generally involves multiple processing steps, including material deposition, pattern formation, and pattern transfer. Material layers may be deposited on a substrate using a variety of techniques, such as spin coating or vapor deposition. Pattern formation is often accomplished using photolithographic methods, in which a photosensitive material (or photoresist) is exposed to actinic radiation through a patterned mask. Photoresist compositions may be selected in part for sensitivity to wavelengths produced by a photolithographic radiation source—such as 248 nm deep ultraviolet (DUV) from KrF excimer lasers, 193 nm DUV from ArF excimer lasers, or 13.5 nm extreme UV (EUV) from tin plasma generated by CO₂ lasers.

After exposure, the photoresist is developed to form a relief pattern. The relief pattern may serve as an etch mask during subsequent pattern-transfer steps by protecting underlying portions of the substrate while allowing exposed areas to be removed. In some pattern-transfer steps, the etch mask may be used to form features in an underlying material. In other pattern-transfer steps, the etch mask may be used to refine existing features. For example, portions of previously patterned lines may be exposed by the etch mask so that the lines can be cut into two or more segments.

As semiconductor device footprints and feature spacings shrink, forming precise patterns and transferring those patterns to substrates with high fidelity has become increasingly challenging. Multiple lithographic exposures and pattern transfers through multiple intermediate layers (such as hard masks or antireflective coatings) are often required. Multi-step, multi-layer approaches help to maintain pattern fidelity but increase process complexity and fabrication costs.

### SUMMARY

In an embodiment, an overcoat composition includes a polymer, a fluorine-free acid generator, a base quencher, and an organic solvent. The fluorine-free acid generator includes a five-membered aromatic ring substituted with one or more electron-withdrawing groups.

In another embodiment, a method of patterning a substrate includes providing a first relief pattern on the substrate, where the first relief pattern includes a first resist; coating the first relief pattern with an overcoat layer including a fluorine-free acid generator; activating the fluorine-free acid generator to form a plurality of acid species within the overcoat layer; diffusing a portion of the plurality of acid species into the first resist to form a solubility-shifted region of the first resist; developing the solubility-shifted region of the first resist; and etching the substrate using the first relief pattern and the overcoat layer as a combined etch mask.

In still another embodiment, a method of patterning a substrate includes providing a first relief pattern on the substrate, where the first relief pattern includes a first resist; coating the first relief pattern with a solubility-shifting agent including a fluorine-free acid generator, the fluorine-free acid generator including a five-membered aromatic ring substituted with one or more electron-withdrawing groups; forming a second resist over the first relief pattern; forming a solubility-shifted region disposed between the first resist and the second resist; developing the solubility-shifted region; and etching the substrate using the first relief pattern and the second resist as a combined etch mask.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate cross-sectional views of different stages of a method of patterning a substrate, wherein FIG. 1A depicts a relief pattern on a substrate, FIG. 1B depicts coating the relief pattern with an overcoat layer, FIG. 1C depicts diffusion of acid species into the relief pattern, FIG. 1D depicts formation of a solubility-shifted region, FIG. 1E depicts development of the solubility-shifted region, and FIG. 1F depicts etching of the substrate using the relief pattern and the overcoat layer as a combined etch mask, according to various embodiments;

FIGS. 2A and 2B illustrate compositions, wherein FIG. 2A depicts a schematic composition for an overcoat comprising a polymer, a fluorine-free acid generator, a base quencher, and an organic solvent, and FIG. 2B depicts a schematic composition for a fluorine-free acid generator comprising a cation and an anion, according to various embodiments;

FIG. 3 illustrates Schemes (P1)-(P3) for polymerized units that may be part of the polymer in an overcoat, according to various embodiments;

FIGS. 4A-4D illustrate example polymerized units that may be part of the polymer in embodiment overcoats, wherein FIG. 4A depicts examples derived from Scheme (P1), FIG. 4B depicts examples derived from Schemes (P2) and (P3), FIG. 4C depicts example copolymers, and FIG. 4D depicts example terpolymers, according to various embodiments;

FIG. 5 illustrates Schemes (S1)-(S5) for anions that may be part of the fluorine-free acid generator in overcoats or in solubility-shifting agents, according to various embodiments;

FIGS. 6A-6D illustrate various example anions derived from Scheme (S1) and comprising cyclopentadienide that may be part of the fluorine-free acid generator in overcoats or in solubility-shifting agents, wherein FIG. 6A depicts examples comprising three or more cyano groups, FIG. 6B depicts examples comprising two or more cyano groups and further comprising a sulfone, FIG. 6C depicts examples comprising two or more cyano groups and further comprising a sulfoxide, and FIG. 6D depicts various other examples, according to various embodiments;

FIG. 7 illustrates various example anions derived from Schemes (S2) and (S3), respectively comprising indenide and fluorenide, that may be part of the fluorine-free acid generator in overcoats or in solubility-shifting agents, according to various embodiments;

FIGS. 8A and 8B illustrate various example anions derived from Schemes (S4) and (S5), respectively comprising heteroaromatic sulfonates with one or two rings, wherein FIG. 8A depicts example sulfonates of furan, oxazole, thiophene, and thiazole, and FIG. 8B depicts example sulfonates of benzofuran, benzoxazole, benzothiophene, and benzothiazole, according to various embodiments;

FIG. 9 illustrates Schemes (S6)-(S8) for cations that may be part of the fluorine-free acid generator in overcoats or in solubility-shifting agents, according to various embodiments;

FIGS. 10A and 10B illustrate various example cations derived from Schemes (S6) and (S7), respectively comprising sulfonium and iodonium cations, wherein FIG. 10A depicts example sulfonium cations and FIG. 10B depicts example iodonium cations, according to various embodiments;

FIG. 11 illustrates various example cations derived from Scheme (S8) comprising a protonated base (BH)⁺, according to various embodiments;

FIG. 12 illustrates Schemes (S9) and (S10) for nonionic structures that may be part of the fluorine-free acid generator in overcoats or in solubility-shifting agents, according to various embodiments;

FIG. 13 illustrates example nonionic structures derived from Scheme (S9) and comprising sulfonic esters of furan, oxazole, thiophene, and thioxazole, according to various embodiments;

FIG. 14 illustrates example base quenchers that may be part of embodiment overcoats, according to various embodiments;

FIG. 15 illustrates example organic solvents that may be part of embodiment overcoats, according to various embodiments;

FIGS. 16A-16F illustrate cross-sectional views of different stages of a method of patterning a substrate, wherein FIG. 16A depicts a relief pattern on a substrate, FIG. 16B depicts coating the relief pattern with a solubility-shifting agent, FIG. 16C depicts formation of a resist over the relief pattern, FIG. 16D depicts formation of a solubility-shifted region disposed between the relief pattern and the resist, FIG. 16E depicts development of the solubility-shifted region, and FIG. 16F depicts etching of the substrate using the relief pattern and the resist as a combined etch mask, according to various embodiments;

FIGS. 17A-17E illustrate cross-sectional views of different stages of a method of patterning a substrate, wherein FIG. 17A depicts coating the relief pattern with a solubility-shifting agent, FIG. 17B depicts formation of a solubility-shifted region over the relief pattern, and FIG. 17C depicts formation of a resist over the relief pattern, such that the solubility-shifted region is disposed between the relief pattern and the resist, FIG. 17D depicts development of the solubility-shifted region, and FIG. 17E depicts etching of the substrate using the relief pattern and the resist as a combined etch mask, according to various embodiments;

FIG. 18 is a flow chart for a method of patterning a substrate, according to various embodiments; and

FIG. 19 is a flow chart for a method of patterning a substrate, according to various embodiments.

### DETAILED DESCRIPTION OF ILLUSTRATIVE EMBODIMENTS

The present disclosure relates to an overcoat composition and methods of patterning substrates. The overcoat composition comprises a polymer, a fluorine-free acid generator comprising a five-membered aromatic ring substituted with one or more electron-withdrawing groups, a base quencher, and an organic solvent. According to various embodiments, the five-membered aromatic ring of the acid generator may be cyclopentadienide, furan, thiophene, pyrrole, or another aromatic heterocycle. Embodiment fluorine-free acid generators provide strong acids (HA) or free acid (protons, H⁺), capable of effecting solubility changes in resist materials while also mitigating environmental concerns associated with fluorinated compounds.

The disclosed compositions enable cleavage of acid-labile groups with very high activation energies (Eₐ), requiring exceptionally strong acids (or superacids). Many such acids are poly- or perfluorinated compounds that may be “forever chemicals,” capable of persisting in the environment for hundreds or thousands of years.

By contrast, embodiment fluorine-free acid generators described herein may produce strong acids or superacids with very high acid-dissociation equilibrium constants Kₐ and very low values of pKₐ=−log₁₀ Kₐ. In some embodiments, fluorine-free acid generators described herein may be superacids generating high local concentrations of free acid. Embodiment fluorine-free acid generators may thus provide sufficient acid strength to enable deprotection of high-Eₐ acid-labile groups while mitigating or entirely eliminating fluorine.

Patterning methods described herein encompass various embodiments comprising use of the fluorine-free acid generators. In some embodiments, a relief pattern on a substrate is coated with an overcoat layer. The acid generator is activated to form acid species within the overcoat layer, and a portion of these acid species diffuse into a resist of the relief pattern to form a solubility-shifted region that may be developed. After development, the overcoat and the relief pattern together provide an etch mask for subsequent etching of the substrate.

In other embodiments, a relief pattern is coated with a solubility-shifting agent comprising the fluorine-free acid generator. Solubility-shifted regions may then be formed through various mechanisms, before or after forming a second resist over the substrate, according to respective embodiments. In certain embodiments, the fluorine-free acid generator may be activated photochemically or thermally, such that acid may be diffused into either resist from the solubility-shifting agent. In certain other embodiments, the fluorine-free acid generator itself may be diffused into either resist and subsequently activated. Development of the solubility-shifted regions again forms an etch mask for subsequent etching of the substrate.

Embodiment methods may enable various kinds of advanced patterning, including anti-spacer patterning, narrow line cuts in existing patterns, and the like, with high fidelity and without requiring multiple photolithography steps. Embodiment methods may also be integrated into conventional semiconductor fabrication workflows. These and additional details are further discussed below.

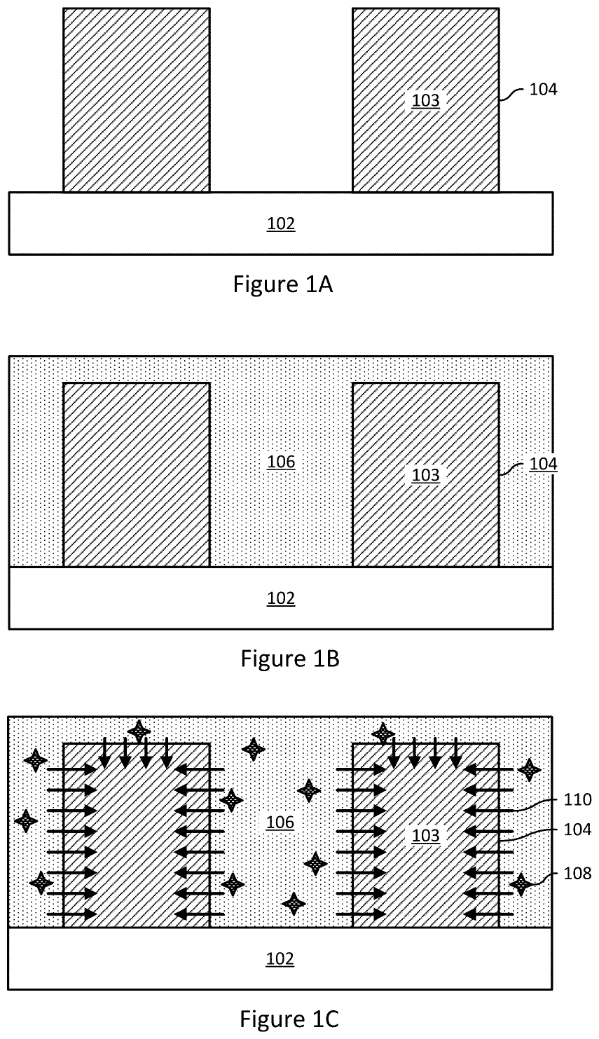

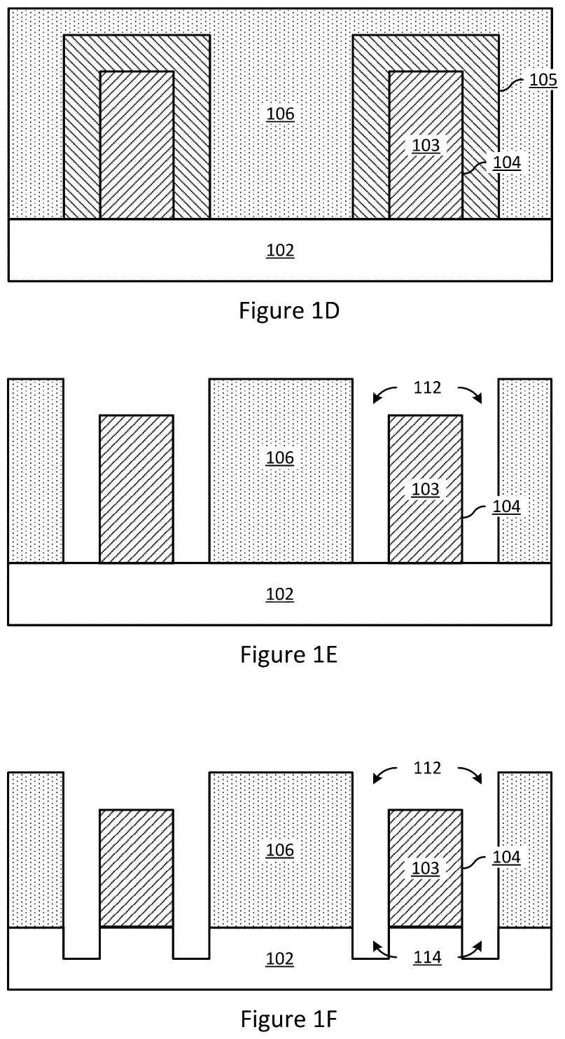

In the detailed description that follows, embodiments are described first with reference to a process flow for patterning a substrate according to an anti-spacer patterning scheme incorporating an overcoat, as illustrated in FIGS. 1A-1F.

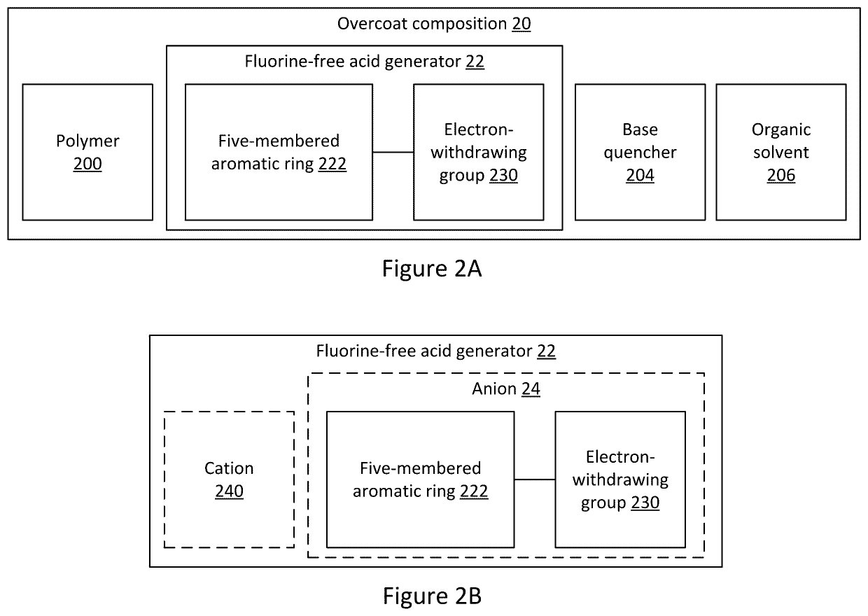

Overcoat compositions are then described with reference to FIGS. 2A and 2B. Embodiment compositions may comprise a polymer, a fluorine-free acid generator comprising a five-membered aromatic ring substituted with one or more electron-withdrawing groups, a base quencher, and an organic solvent, among other components. In some embodiments, the fluorine-free acid generator may comprise ions, as illustrated in FIG. 2B; in certain embodiments, a cation of the fluorine-free acid generator may be a proton (H+), such that the fluorine-free acid generator may itself be a strong acid or a superacid that generates free acid.

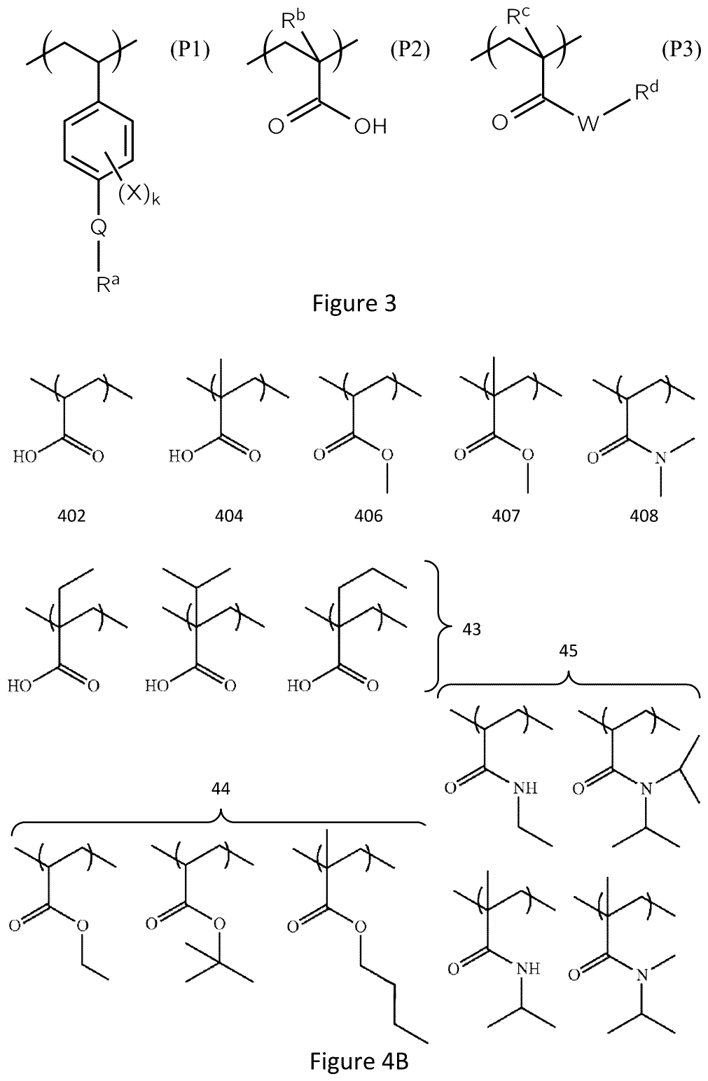

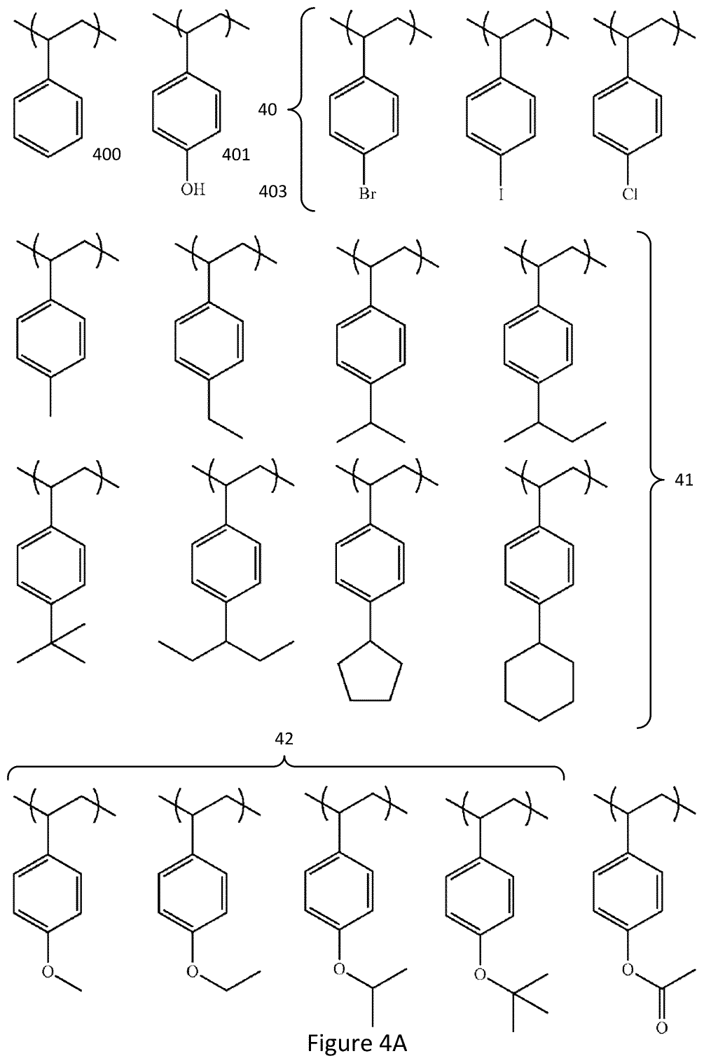

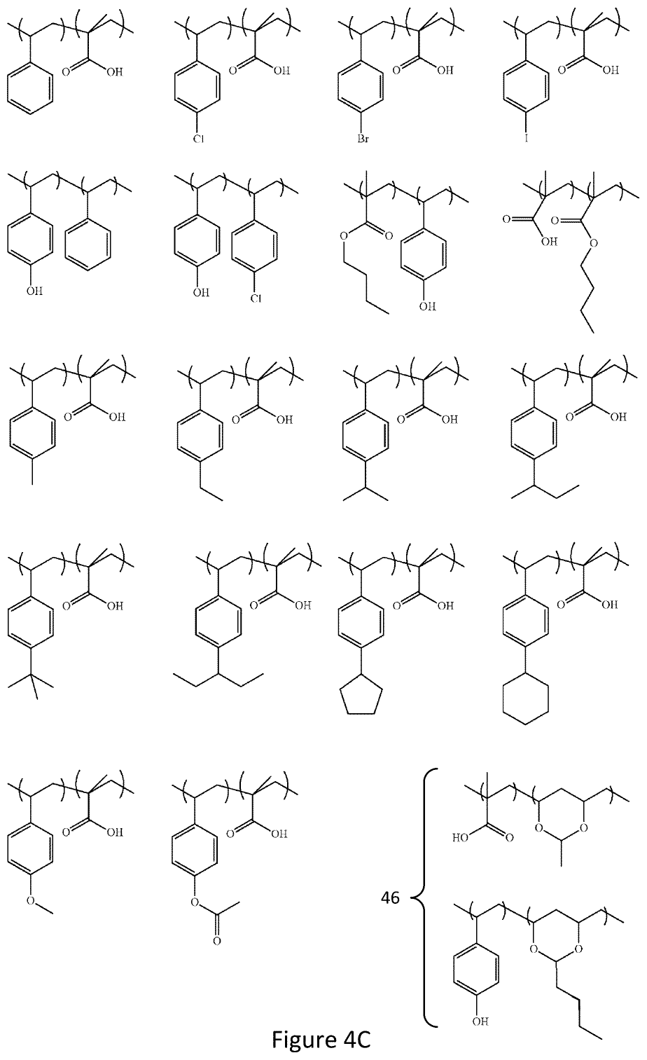

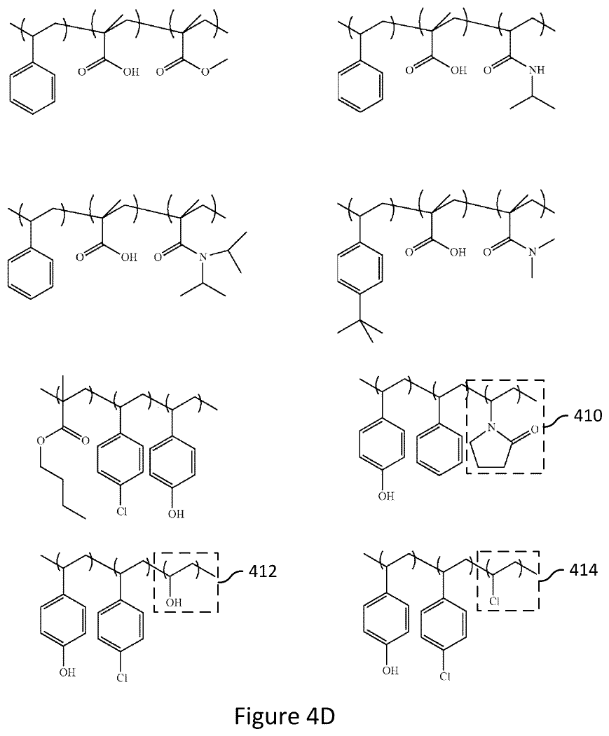

Various embodiment polymers that may be part of the compositions are described with reference to Schemes (P1)-(P3) of FIG. 3. Exemplary polymers, copolymers, and terpolymers are described with reference to FIGS. 4A-4D.

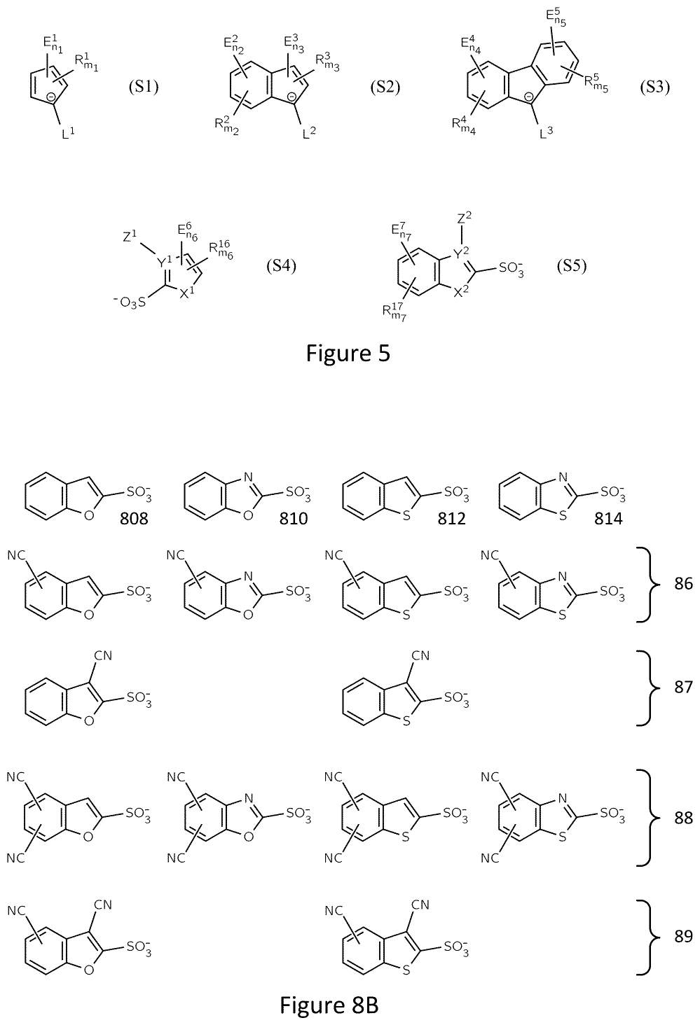

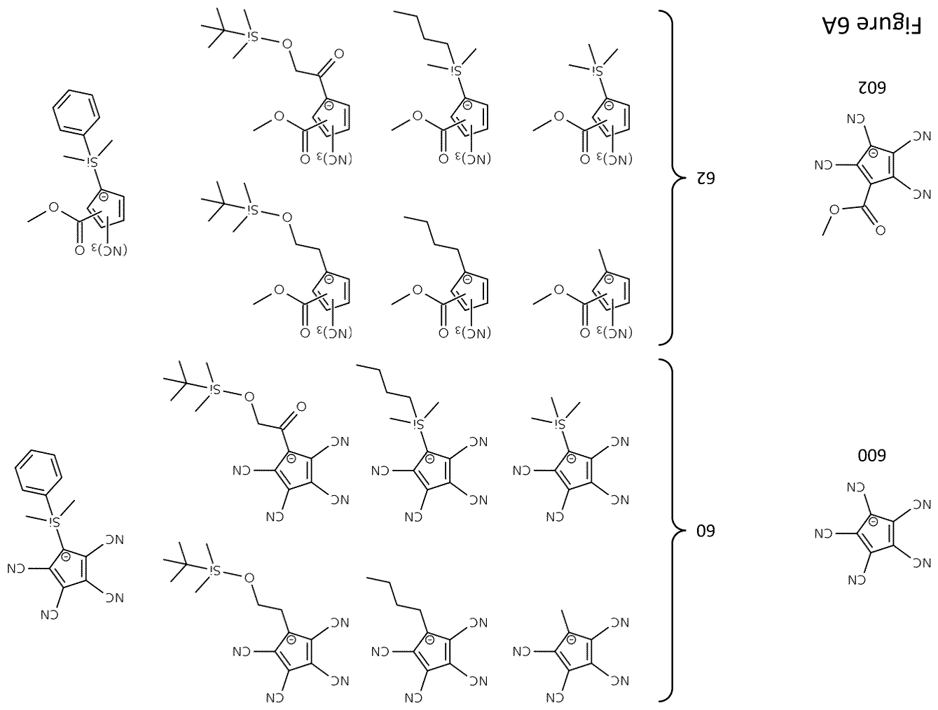

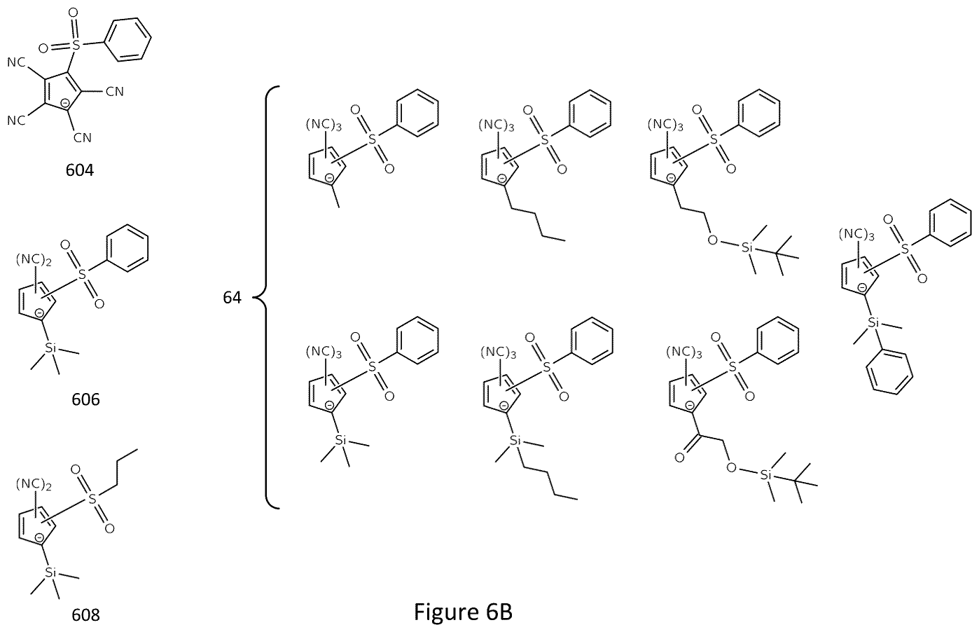

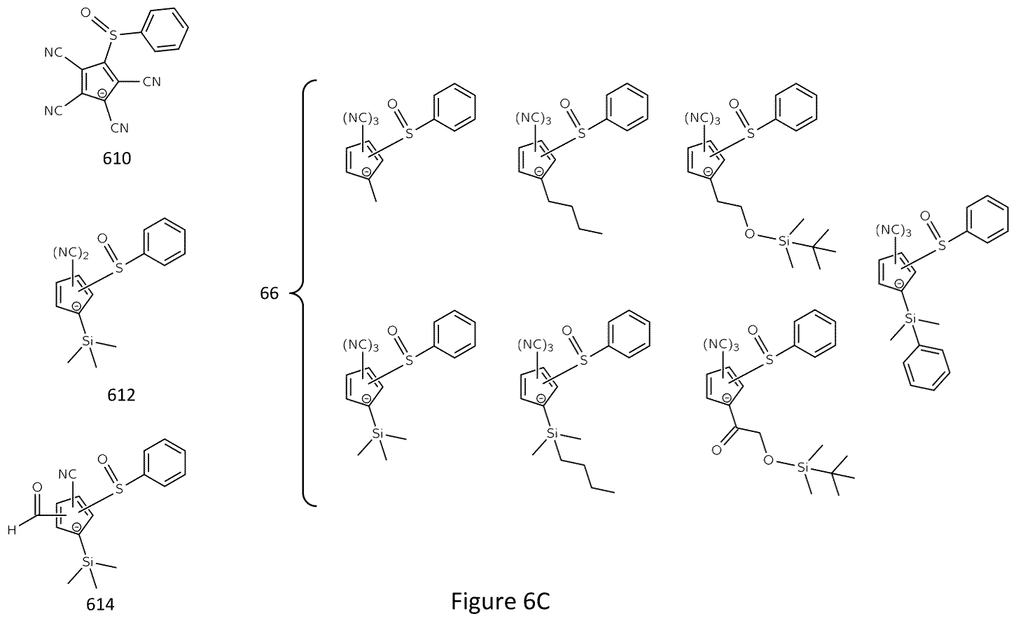

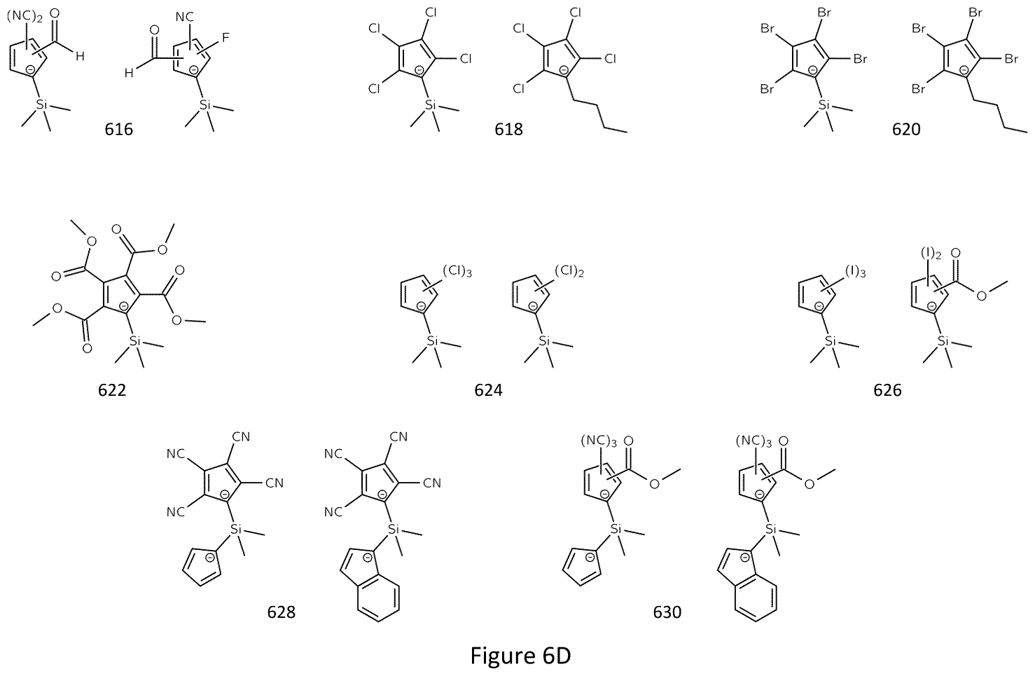

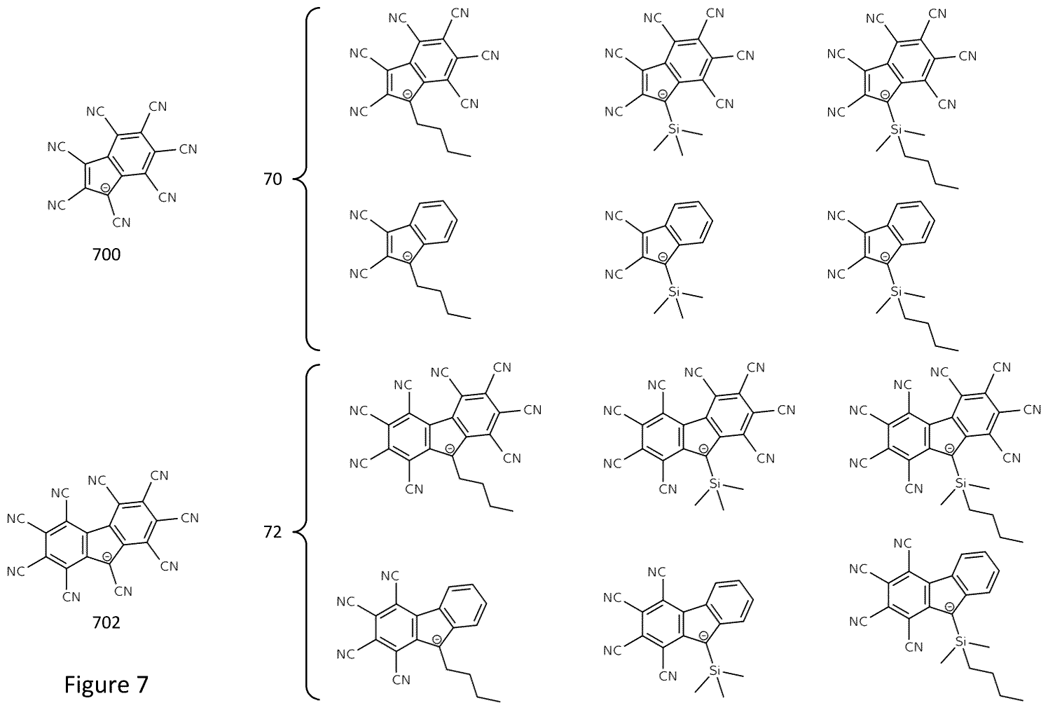

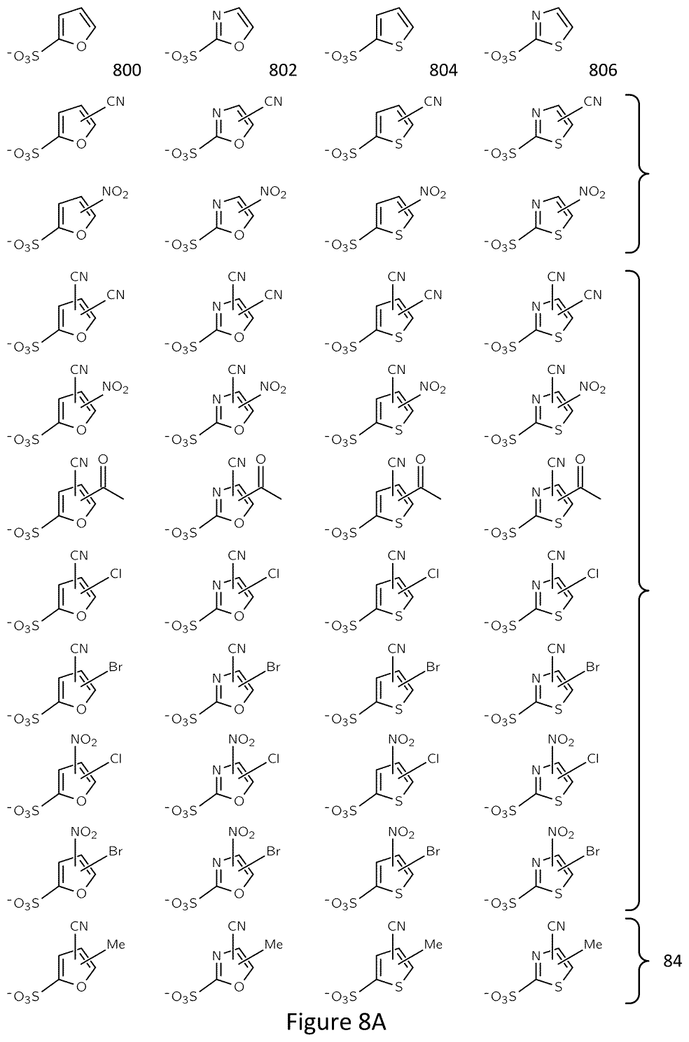

Fluorine-free acid generators comprising ions are then described, according to various embodiments. Various embodiment anions that may be part of the fluorine-free acid generator are described with reference to Schemes (S1)-(S5) of FIG. 5. Exemplary anions are presented, including anions comprising cyclopentadienide (Cpide) (FIGS. 6A-6D); anions comprising indenide and fluorenide (FIG. 7); and anions comprising heteroaromatic sulfonates (FIGS. 8A and 8B).

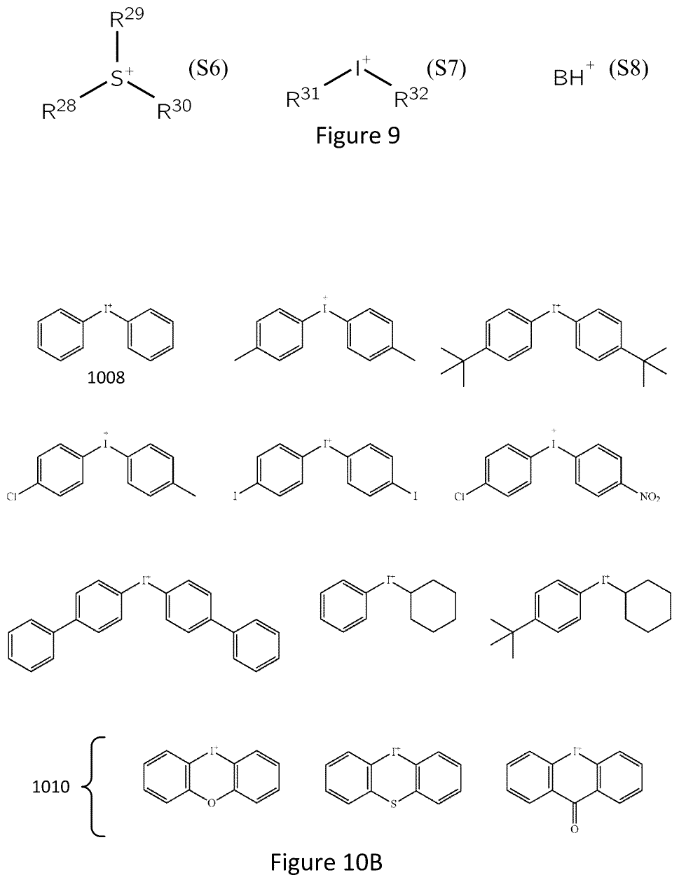

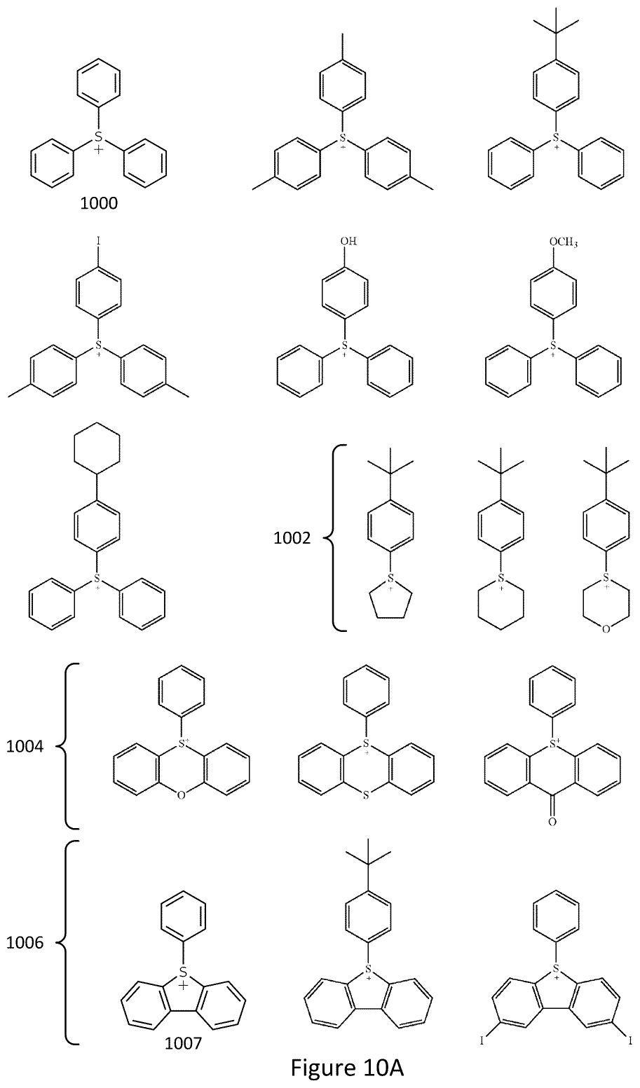

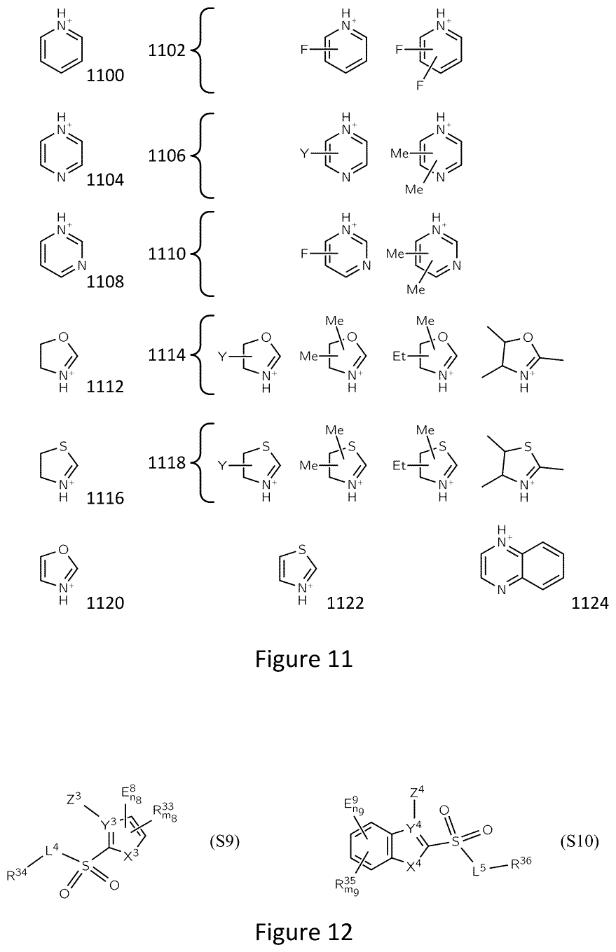

Various embodiment cations that may be part of the fluorine-free acid generator are then described with reference to Schemes (S6)-(S8) of FIG. 9. Exemplary cations are presented, including sulfonium cations (FIG. 10A), iodonium cations (FIG. 10B), and protonated bases (FIG. 11).

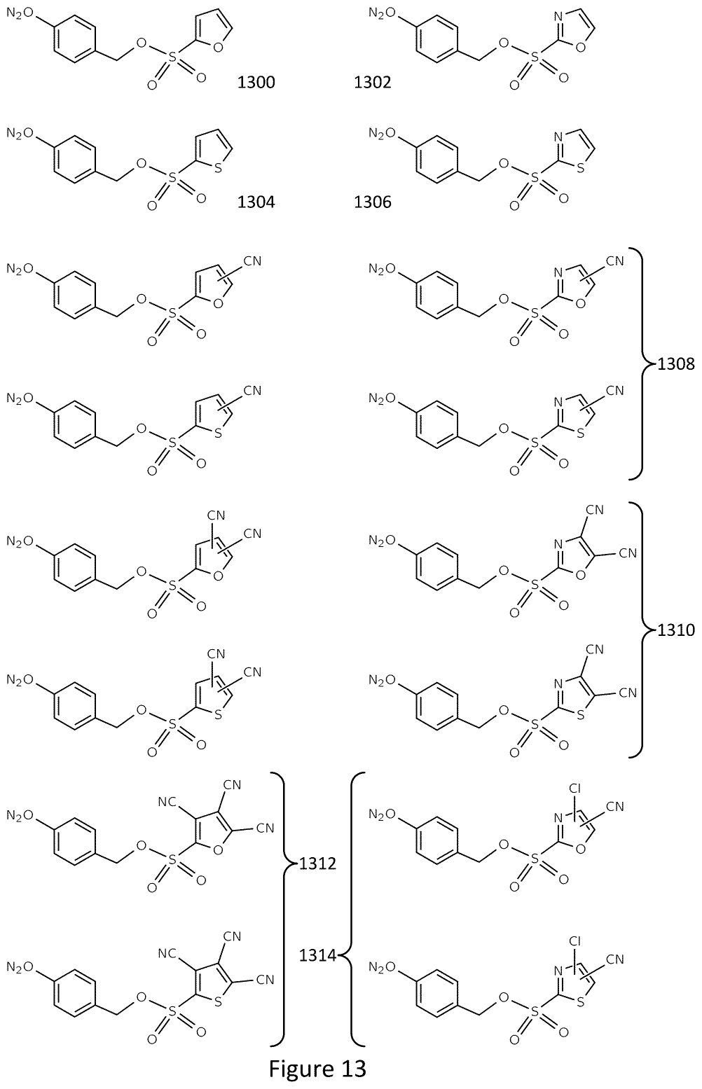

Some embodiment fluorine-free acid generators may comprise a nonionic structure, as described with reference to Schemes (S9)-(S10) of FIG. 12. Exemplary compounds are presented in FIG. 13.

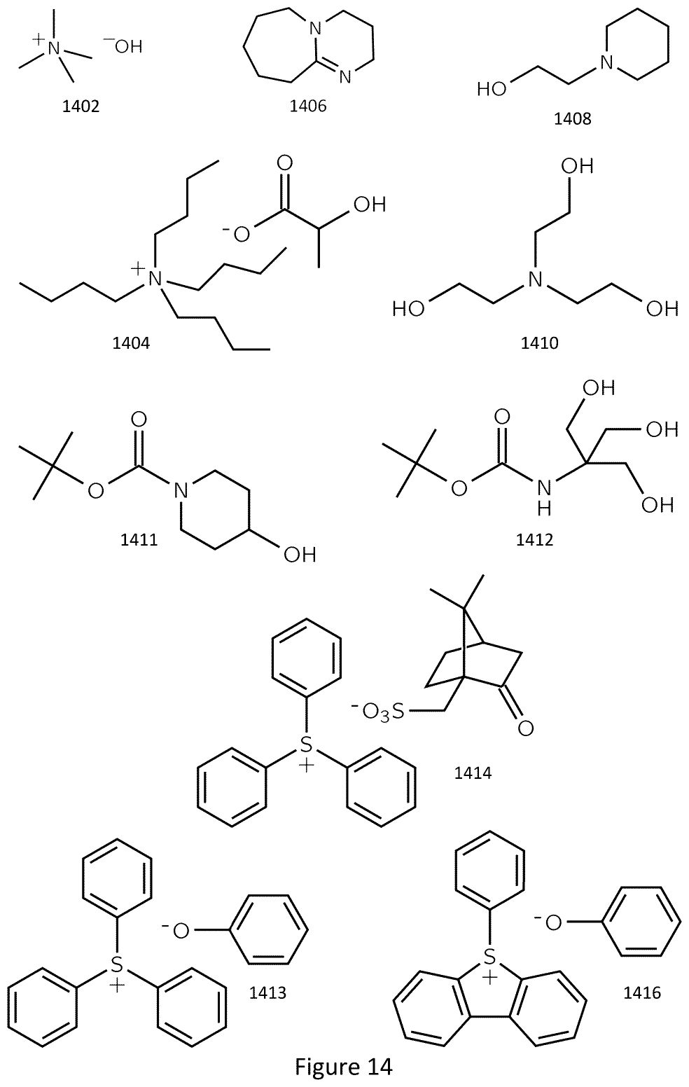

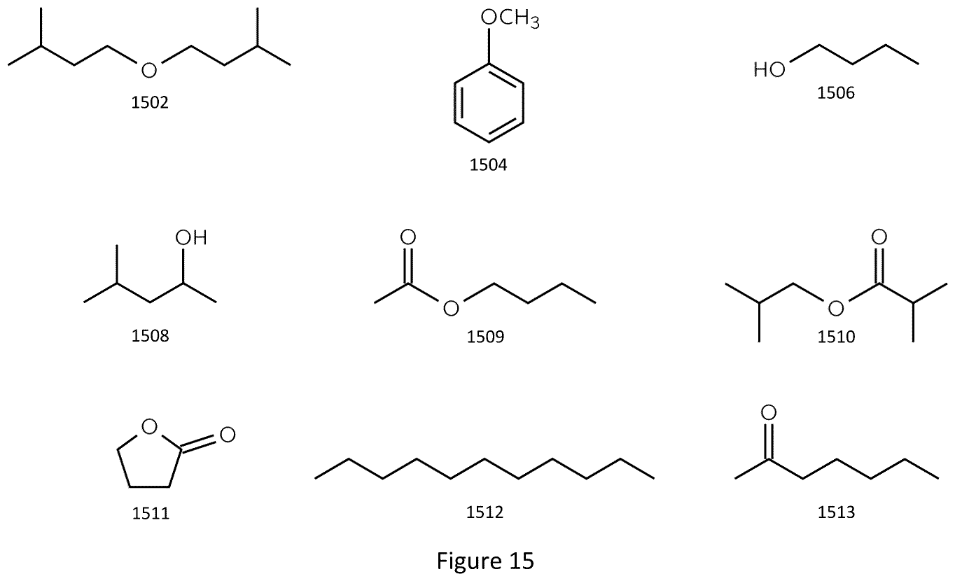

Embodiment base quenchers and solvents that may be part of various overcoat compositions are then described with reference to FIG. 14 and FIG. 15, respectively.

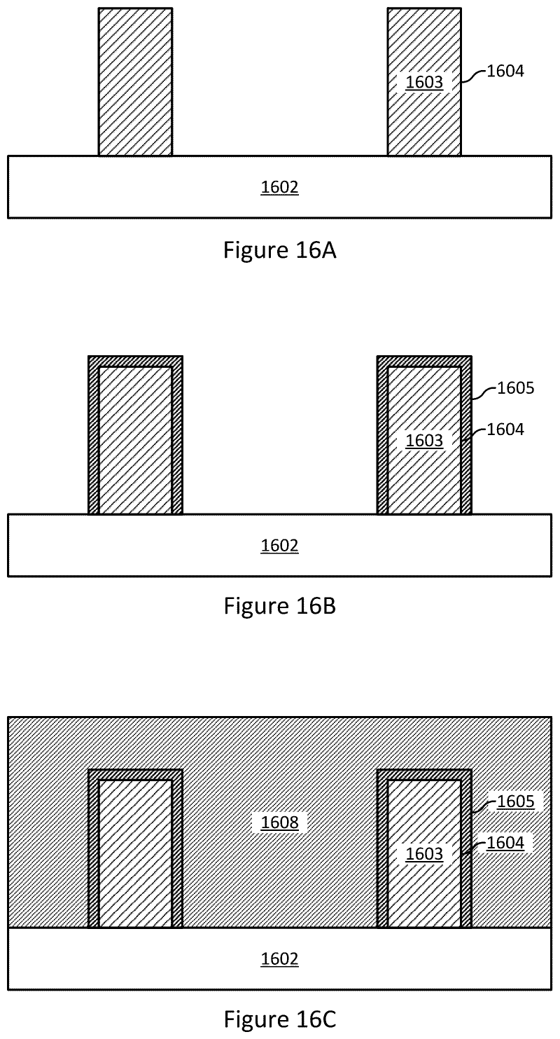

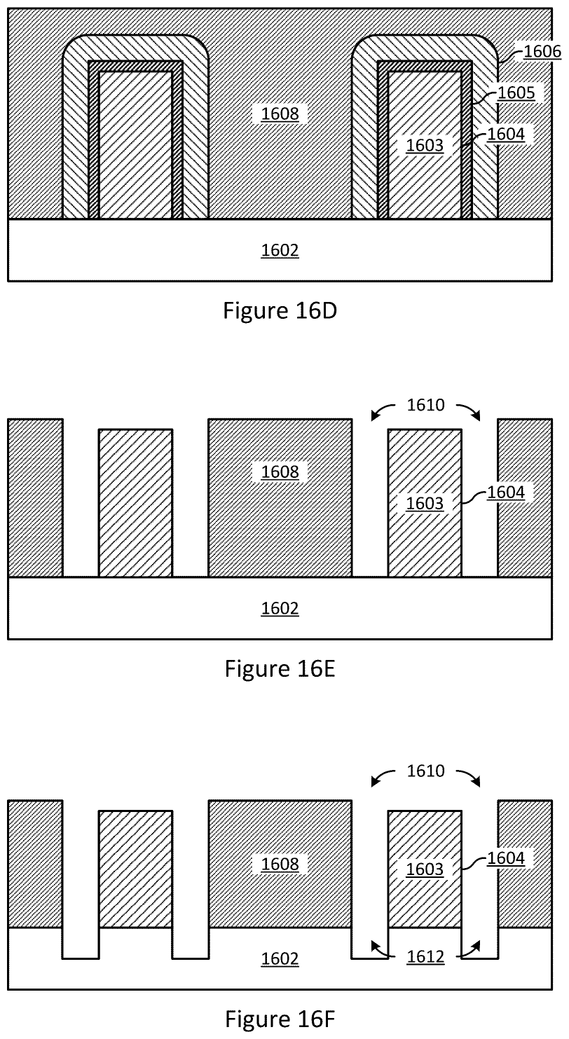

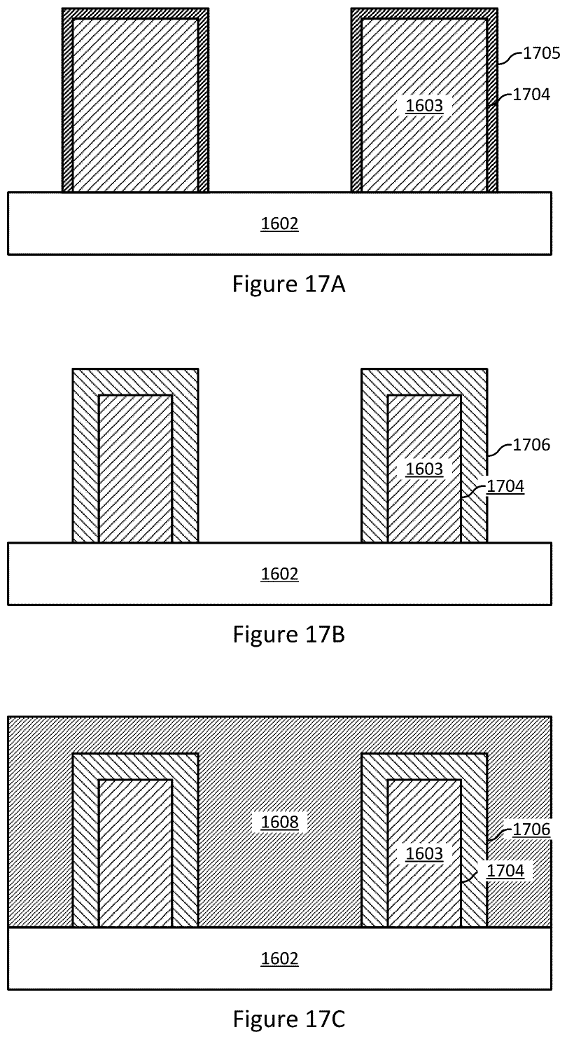

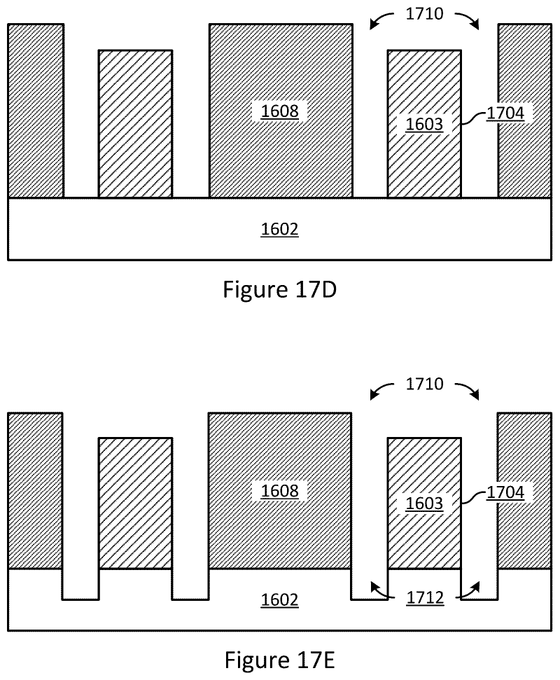

Other embodiment patterning methods comprise the use of a solubility-shifting agent including a fluorine-free acid generator, rather than an overcoat layer, as described with reference to FIGS. 16A-16F and FIGS. 17A-17E. The solubility-shifting agent may be coated or deposited over a first resist and then used to form solubility-shifted regions in a second resist or the first resist, implementing distinct anti-spacer processes in the respective embodiments.

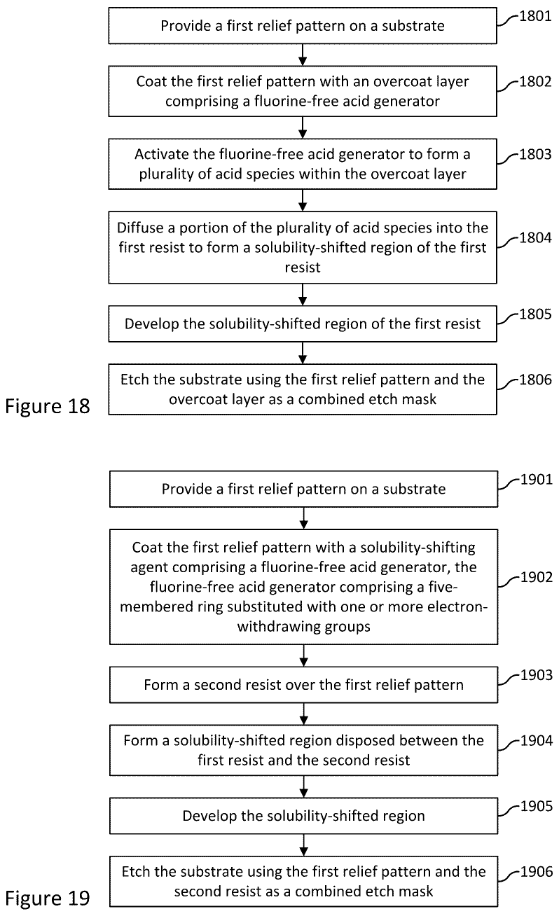

To conclude the detailed description, two more general methods of patterning a substrate are described with reference to flow charts presented in FIGS. 18 and 19.

FIG. 1A depicts an initial stage of patterning a substrate according to various embodiments, and in particular depicts a relief pattern 104 provided on a substrate 102.

The substrate 102 may be a part of, or include, a semiconductor device or a semiconductor structure, and may be formed in any suitable manner, such as by any combination of deposition, lithography, and etch techniques. For example, the semiconductor structure may comprise the substrate 102, in which various device regions are formed. In certain embodiments, the substrate 102 may comprise isolation regions (such as shallow-trench isolation regions), diffusion regions, and other regions formed therein. In various embodiments, the substrate 102 may be patterned or embedded in other components of the semiconductor device or the semiconductor structure.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or another compound semiconductor. In other embodiments, the substrate 102 may comprise heterogeneous layers such as silicon germanium on silicon, gallium nitride on silicon, silicon carbon on silicon, or layers of silicon on a silicon or SOI substrate.

The relief pattern 104 may comprise a resist 103 patterned through photolithographic processes. Generally, the resist 103 may be a chemically amplified photosensitive composition that comprises a polymer, a photoacid generator, and a solvent. In one or more embodiments, the polymer of the resist 103 comprises acid-labile groups.

The polymer of the resist 103 may be any standard polymer conventionally used in photoresist material. In particular embodiments, the polymer of the resist 103 may comprise polymerized units of vinyl aromatic monomers such as styrene and 4-hydroxystyrene (p-hydroxystyrene), acrylate, methacrylate, norbornene, and combinations thereof.

In some embodiments, monomers comprising reactive functional groups may be present in the polymer in a protected form. For example, the —OH group of a p-hydroxystyrene unit may be protected with a tert-butoxycarbonyl protecting group. Such protecting groups may alter the reactivity and solubility of the polymer included in the resist 103.

In order to provide a relief pattern 104 like that depicted in FIG. 1A, a layer of resist 103 may first be formed on the substrate 102 using techniques such as spin coating or vapor deposition. The layer of resist 103 is exposed to actinic radiation through a patterned mask, which causes the photoacid generator of the resist 103 to generate acid in the exposed regions.

Post-exposure baking may be used to diffuse acid within exposed regions of the layer of resist 103 and to catalyze reactions such as the cleavage of acid-labile protecting groups, creating a solubility differential between exposed and unexposed regions. Development of the resist 103 with an appropriate developer then removes either the exposed portions (positive tone) or the unexposed portions (negative tone) of the layer of resist 103, resulting in the relief pattern 104.

As shown in FIG. 1A, the relief pattern 104 comprises a plurality of features with substantially vertical sidewalls. These features of the relief pattern 104 may be separated by gaps exposing portions of the substrate 102. Features of the relief pattern 104 and gaps may have a minimum width (critical dimension) between 30 nm and 1 μm, according to various embodiments. In some embodiments, the critical dimension of the relief pattern 104 may be between 20 nm and 80 nm.

FIG. 1B depicts the application of an overcoat 106 to the relief pattern 104, according to various embodiments. The overcoat 106 is coated over the relief pattern 104 and exposed portions of the substrate 102.

The overcoat 106 may be applied using techniques such as spin coating or vapor deposition to form a uniform layer over the relief pattern 104. A thickness of the overcoat 106 may be any thickness desirable for subsequent processing steps and sufficient to cover the relief pattern 104 and fill any gaps. In certain embodiments, the overcoat 106 may have a thickness between 15 nm and 150 nm. In some embodiments, a post-application bake may help to set the overcoat 106 and drive off residual solvent.

According to various embodiments, the overcoat 106 comprises a polymer, a fluorine-free acid generator, a base quencher, and an organic solvent. The fluorine-free acid generator in the overcoat 106 may be a strong acid or superacid that generates free acid; a photoacid generator (PAG); a thermal acid generator (TAG); or an acid generator having sensitivity to both light and heat, according to various embodiments. When activated by an appropriate stimulus (light, heat, or both, in the respective embodiments), the acid generator may produce a plurality of acid species within the overcoat 106.

The polymer of the overcoat 106 may allow for controlled application of the overcoat composition. The organic solvent may facilitate application of the overcoat 106 while being compatible with the resist 103, such that it does not substantially blur, damage, or dissolve the relief pattern 104. The base quencher of the overcoat 106 may scavenge acid species generated by the acid generator, enabling tuning of a mean free path for acid diffusion even for a fixed choice of embodiment acid generator and process conditions. Consequently, the base quencher may enable tuning of an associated diffusion depth of acid species into an adjacent material, such as a resist, and thus may enable tuning of a critical dimension for solubility-shifted regions that form in the resist. Components of various embodiment overcoat compositions will be described in further detail below with reference to FIGS. 2-15.

FIG. 1C depicts the fluorine-free acid generator having been activated to form a plurality of acid species 108 (represented by the 4-pointed stars distributed throughout the overcoat 106) and diffusion of acid species (indicated by arrows 110) into the resist 103, according to various embodiments.

Activation of the acid generator may be photochemical (triggered by exposure to actinic radiation), thermal (triggered or tuned by heating), or both, according to various embodiments. For photochemical activation, the overcoat 106 may be exposed to radiation having any appropriate wavelength, such as 248 nm or 193 nm deep ultraviolet (DUV) or another suitable wavelength. In some embodiments, the exposure may be a flood exposure of the entire substrate; in other embodiments, the exposure may be performed with a mask, for example, to prepare more precise cut patterns.

For thermal activation, the workpiece depicted in FIG. 1C may be heated to a temperature sufficient to trigger the acid generator. In some embodiments, a trigger temperature of a TAG comprising the fluorine-free acid generator may be between 50° C. and 180° C. In certain embodiments, the trigger temperature of a TAG comprising the fluorine-free acid generator may be between 90° C. and 140° C.

In other embodiments in which the acid generator comprises strong acid or superacid molecules, heating to a temperature between 50 C and 180 C or between 90 C and 140 C may tune (or continuously shift) the acid-dissociation equilibrium constant Kₐ to higher values and correspondingly tune the pKₐ to lower values. The strong acid or superacid molecules of the acid generator may then dissociate more completely and produce higher concentrations of free acid (protons). In certain embodiments, temperature tuning of the pKₐ may thus allow tuning of the diffusion depth and critical dimension of solubility-shifted regions produced by the acid species, according to embodiments.

According to various embodiments, the acid species 108 may be free acid (protons); in other embodiments, the acid species may be strong acid or superacid molecules (HA), or even unactivated molecules of the fluorine-free acid generator. In still other embodiments, the acid species may comprise free acid, strong acid molecules, superacid molecules, unactivated molecules of the fluorine-free acid generator, or a combination thereof.

Undissociated acid (HA) may subsequently dissociate to form free acid (H⁺) and a conjugate base A⁻, according to various embodiments. Mean free paths for dissociation of free acid or undissociated acid may be further tuned, in various embodiments, by a choice of conjugate base A⁻, a choice of base quencher, or both. Stronger acids (lower pKₐ) may enable cleaving acid-labile groups with high activation energies and may have weaker conjugate bases.

In some embodiments, the fluorine-free acid generator may be diffused into the resist 103 directly, before or after activation. For example, some acid generator molecules may diffuse into the resist 103 and then be activated to generate other types of acid species 108 (such as H⁺ or HA), directly within the resist 103. The relative importance of a direct-diffusion mechanism may be controlled by factors such as the relative sizes of the acid generator molecules and the other types of acid species 108, as well as process conditions of the diffusion, according to various embodiments.

The diffusion process may be controlled by various factors, including diffusion temperature, diffusion time, the nature of the acid species 108, absolute and relative concentrations of acid and the base quencher of the overcoat 106, other components of the overcoat 106 or of the resist 103, and the like. In various embodiments, the diffusion may be carried out or promoted by a baking process, also known as a post-exposure bake or a diffusion bake.

According to various embodiments, the diffusion bake may be performed at a temperature between 50° C. and 180° C. In some embodiments, the diffusion bake temperature may be between 80° C. and 130° C.; in certain embodiments, the diffusion bake temperature may be between 80° C. and 100° C. According to various embodiments, the diffusion bake may be performed for a duration between 30 s and 90 s, or for any duration producing a desired diffusion distance of the acid species 108 into the resist 103.

In FIG. 1D, a solubility-shifted region 105 appears as a distinct border region between the resist 103 and the overcoat 106 formed as a result of the diffusion of acid species 108 from the overcoat 106 into the resist 103. In the solubility-shifted region 105, the acid species 108 have reacted with components of the resist 103, for example, by cleaving acid-labile protecting groups in the polymer of the resist 103. According to various embodiments, cleavage of acid-labile groups and other acid reactions shift the solubility characteristics of the affected region of the resist 103, making them soluble in developers that would not otherwise dissolve the resist 103. In some embodiments, developer solvents suitable for dissolving the solubility-shifted region 105 may comprise an aqueous base developer or an organic solvent developer.

For example, in embodiments in which the resist 103 contains a polymer with t-BOC protecting groups on phenolic units, such as poly(4-tert-butoxycarbonylstyrene), the acid would catalyze the removal of these groups, converting protected phenolic units to free phenolic units, such as poly(4-hydroxystyrene). The presence of highly polar —OH groups may significantly increase the solubility of the polymer in aqueous alkaline developers or organic developers with relatively polar functionalities, such as alcohols.

A thickness of the solubility-shifted region 105 corresponds to a diffusion depth of the acid species 108 into the resist 103. In some embodiments, the solubility-shifted region 105 extends into the resist 103 to a depth between 5 nm and 60 nm. For example, in various embodiments, the thickness of the solubility-shifted region 105 may range between a lower limit of 5, 10, 15, 20, or 25 nm and an upper limit of 40, 45, 50, 55, or 60 nm, where any lower limit may be paired with any mathematically compatible upper limit.

In some embodiments, the thickness of the solubility-shifted region 105 may be tuned to correspond to a desired width of a line to be patterned into the substrate 102. In other embodiments comprising line cutting, the thickness of the solubility-shifted region 105 may be tuned to match a critical dimension of the desired line cut.

In FIG. 1E, the solubility-shifted region 105 is developed, creating a plurality of openings 112 that expose portions of the substrate 102. Further, and according to embodiments, the openings 112 are disposed between the relief pattern 104 and the overcoat 106, such that the relief pattern 104 and the overcoat 106 are separated spatially by the openings 112. The development may be performed using an appropriate developer solution selected based on the composition of the resist 103, the solubility-shifted region 105, and the overcoat 106.

In some embodiments, the solubility-shifted region 105 may be developed in a single step, with a single developer or developer mixture that also removes any overburden of the overcoat 106. In these embodiments, the overcoat 106 may be slightly soluble in the developer (or developer mixture) that removes the solubility-shifted region 105. In certain embodiments, the overcoat 106 and the developer may be selected such that a dissolution rate of the overcoat 106 in the developer is low, but non-zero. In some embodiments, a dissolution rate of the overcoat 106 in the developer may be between 0.5 Å/s and 50 Å/s. In certain embodiments, the dissolution rate may be between 1 Å/s and 10 Å/s.

In other embodiments, a two-step development process may be employed. First, a developer for the overcoat 106 (such as an organic solvent) may be used to remove any overburden. A second development step, using a different developer selected for compatibility with the overcoat 106, may then remove the solubility-shifted region 105.

The development may be carried out using any suitable method, including dipping the substrate in a bath filled with the developer for a fixed time (dip method); dispensing the developer onto a substrate such that the surface is completely covered and the developer is held on the surface by surface tension, then keeping the substrate submerged for a fixed time (puddle method); spraying the developer onto a stationary substrate (spray method); or spraying the developer from a nozzle while optionally rastering the nozzle over a moving substrate (dynamic dispense method).

A width of the openings 112 corresponds to the thickness of the solubility-shifted region 105 that was developed away. The width of the openings 112 may be between 5 nm and 60 nm, according to embodiments. In some embodiments, the openings 112 may have width between 5 nm and 30 nm, or between 5 nm and 15 nm.

After development, and in various embodiments, a height of the overcoat 106 over the substrate 102 may differ from a height of the relief pattern 104, creating a non-planar top surface across the structure. In embodiments in which a height difference may be desirable, the height difference may be controlled through an initially applied thickness of the overcoat 106 and by the development process. In other embodiments, the height difference may be eliminated by methods such as tuning of the overcoat composition, tuning of the coating or deposition process, or chemical-mechanical planarization.

In some embodiments, though not as illustrated, there may also be some overhang of the overcoat 106 above the plurality of openings 112 after initial development. Overhang may be removed by tuning a coated or deposited thickness of the overcoat, by extending the development process, by chemical-mechanical planarization, by controlled etching, or by other suitable methods, according to embodiments.

The relief pattern 104 and the overcoat 106 may be used together as a combined etch mask for forming features in the substrate 102. FIG. 1F depicts a partially etched workpiece in which etched features 114 extend below an original surface of the substrate 102, with intact portions of the substrate 102 covered by the relief pattern 104 and the overcoat 106.

Etching may be carried out using various techniques according to different embodiments. The etch process may be an isotropic or anisotropic, wet or dry etch process, as may be desirable. In various embodiments, an anisotropic dry etch, such as plasma etching or reactive ion etching, may be performed.

In some embodiments comprising dry etching, an etch chemistry may comprise a fluorocarbon or a fluorohydrocarbon; an oxygen-containing gas such as elemental oxygen, ozone, or water vapor; or a haloacid such as hydrogen bromide or hydrogen fluoride. The etch chemistry may be chosen for selectivity between the substrate 102 and the mask materials (resist 103 and overcoat 106), such that the mask remains intact for a sufficient length of time to etch the substrate 102 to a desired depth, according to embodiments.

After the etching process is complete, any remaining portions of the resist 103 and the overcoat 106 may be removed using appropriate stripping processes, leaving the substrate 102 with the etched features 114. These etched features 114 may form semiconductor device structures, such as contacts, vias, trenches, or other circuit elements, in various embodiments. In some embodiments, the etched features 114 may be cuts in existing structures (such as lines) patterned on the substrate 102.

Having described a method of patterning substrates using an overcoat comprising a fluorine-free acid generator, overcoat compositions enabling such patterning processes will now be introduced, according to various embodiments. To facilitate clear understanding of these compositions and their components, it is useful to establish certain nomenclature regarding chemical structures and functional groups that will be referenced throughout the remainder of the detailed description.

With reference now to FIG. 2A, a schematic representation of an overcoat composition 20 is presented, according to various embodiments of the present disclosure. Embodiment overcoat compositions 20 may enable patterning processes such as those described with reference to FIGS. 1A-1F, as well as other such processes.

The overcoat composition 20 comprises a polymer 200, a fluorine-free acid generator 22, a base quencher 204, and an organic solvent 206. The overcoat composition 20 may have a total solid content (i.e., excluding the organic solvent 206) between 0.5 wt % and 10 wt % of a total weight of the composition, according to embodiments. In some embodiments, the total solid content may be between 0.5 wt % and 3 wt % of the total weight. The organic solvent 206 may comprise the remaining weight, in the respective embodiments.

The polymer 200 may serve as a matrix material for the overcoat composition 20, providing appropriate film-forming properties and compatibility with materials of an underlying resist (such as resist 103). The polymer 200 may include various functional groups and structural features that influence properties such as solubility in a given organic solvent 206, solubility in a given developer, thermal stability, and etch resistance. Various embodiment polymers will be described in detail with reference to FIGS. 3 and 4A-4D.

Within the solid content of the overcoat composition 20, the polymer 200 may generally comprise a majority of the material, between 60 wt % and 99.9 wt % of a solid weight. In some embodiments, the polymer 200 may comprise between 80 wt % and 99 wt %, or between 85 and 98 wt %, of the solid weight.

The fluorine-free acid generator 22 comprises a five-membered aromatic ring 222 substituted with at least one electron-withdrawing group (EWG) 230. The five-membered aromatic ring 222 may be a carbon-based ring such as cyclopentadienide; a heterocyclic ring such as furan, thiophene, or pyrrole; or another aromatic ring or heterocycle, according to various embodiments. In some embodiments, the overcoat composition 20 may comprise two or more fluorine-free acid generators 22 with different structures.

In some embodiments, the five-membered aromatic ring 222 may be fused to one or two C₆ aryl groups, such as benzene, aniline, phenol, halobenzene, nitrobenzene, or the like. It should be understood that when the five-membered aromatic ring 222 is fused to one or two C₆ aryl groups, the resulting fused ring system includes 4 or 8 carbon atoms in addition to those of the five-membered aromatic ring 222, according to the respective embodiments.

The EWG 230 may draw electron density away from neighboring atoms towards itself by a resonance effect, an inductive effect, or a hyperconjugation effect; by another mechanism; or by a combination thereof. According to various embodiments, and in addition to other examples provided below, the EWG 230 may be a weakly electron-withdrawing group, such as halogen; a moderately electron-withdrawing group, such as aldehyde (—CHO), ketone (—COR), carboxylic acid (—CO₂H), ester (—CO₂R), or amide (—CONH₂); or a strongly electron-withdrawing group, such as trihalide (—CCl₃), cyano (—CN), sulfone (—SO₂R), sulfonate (—OSO₂R), or nitro (—NO₂). In some embodiments, the electron-withdrawing groups 230 are specifically selected to be free of fluorine (i.e., to exclude fluorine atoms and fluorine-containing substituents).

In various embodiments, the fluorine-free acid generator 22 may be an ionic acid generator, i.e., it may comprise at least one (positively charged) cation 240 and at least one (negatively charged) anion 24, as illustrated in FIG. 2B. That the fluorine-free acid generator 22 is not required to be ionic is emphasized by dashed borders of the cation 240 and the anion 24. In certain embodiments, the fluorine-free acid generator 22 may be a zwitterion, such that the cation 240 and the anion 24 are part of the same molecule.

The cation 240 may serve as a counterion to the anion 24. According to various embodiments, the cation 240 may comprise an organic cation such as a sulfonium cation, an iodonium cation, or a protonated base represented by a formula (BH)⁺, such as an ammonium cation (NH₄⁺). In some embodiments, the cation 240 may comprise a phosphonium cation (HPR₃⁺) or an alkali metal cation compatible with a desired semiconductor manufacturing flow. In certain embodiments, the cation 240 may be a proton (H⁺), such that the fluorine-free acid generator 22 is or comprises a strong acid or a superacid.

In some embodiments, the anion 24 may carry multiple negative charges (such as a charge of −2, −3, or higher) and may be associated with multiple cations 240, which may be of the same type or of mixed types. In other embodiments, the cation 240 may carry multiple positive charges (such as a charge of −2, −3, or higher), and may be associated with multiple anions 24, which may be of the same type or of mixed types. In still other embodiments, both the cation 240 and the anion 24 may have charges with absolute value greater than 1. In certain embodiments comprising multiple negative charges on the anion 24, the multiple cations 240 may comprise one or more protons, such that the fluorine-free acid generator 22 may be or comprise a mono-, di-, tri-, or higher polyprotic strong acid or superacid.

Various embodiment fluorine-free acid generators 22 described herein, whether nonionic or ionic, may exclude fluorine entirely, such that no part of the fluorine-free acid generator 22 comprises a fluorine atom. In other embodiments, the fluorine-free acid generator 22 may entirely exclude carbon-fluorine bonds, such as those of terminal fluorine (—F) substituted for hydrogen in a carbon-hydrogen bond, divalent perfluoromethylene groups (—CF₂-), or monovalent perfluoromethyl groups (—CF₃). By extension, such embodiments may exclude singly and poly-fluorinated groups such as —CH₂F, —CH₂CF₃, —CH₂CF₂CH₃. Greater degrees of freedom from fluorine may enable reduced concentrations of environmentally persistent poly- and perfluorinated “forever chemicals” in manufacturing wastes.

Further embodiments and examples of the fluorine-free acid generator 22 are described below. Embodiment anions 24 are described with reference to FIGS. 5-8 and may be combined with embodiments cations 240 described with reference to FIGS. 9-11, according to various embodiments. Nonionic embodiments of the fluorine-free acid generator 22 are described with reference to FIGS. 12 and 13.

Within the solid content of the overcoat composition 20, the fluorine-free acid generator 22 may comprise between 0.1 wt % and 20 wt % of the total solid weight. In some embodiments, the fluorine-free acid generator 22 may comprise between 1 wt % and 10 wt % of the total solid weight. In certain embodiments, the fluorine-free acid generator 22 may be incorporated into a polymer (which may be the polymer 200 or a separate polymer). In embodiments in which the fluorine-free acid generator 22 is incorporated in the polymer 200, it may have an abundance between 1 mol % and 30 mol % based on total repeating units of the polymer 200. In some embodiments, the fluorine-free acid generator 22 may have an abundance between 1 mol % and 10 mol % based on total repeating units of the polymer 200.

In embodiments in which the fluorine-free acid generator 22 is incorporated into a separate polymer from polymer 200, the fluorine-free acid generator 22 may have an abundance between 25 mol % and 100 mol % based on total repeating units of the separate polymer. In other such embodiments, the abundance of the fluorine-free acid generator 22 may be between 80 mol % and 100 mol % based on total repeating units of the separate polymer.

With further reference to FIG. 2A, the base quencher 204 is included in the overcoat composition 20 to enable fine control of the diffusion of acid (such as the acid species 108) generated by the fluorine-free acid generator 22. By partially neutralizing the generated acid, the base quencher 204 may enable formation of solubility-shifted regions (such as the solubility-shifted region 105) with precise dimensions. The base quencher 204 may be selected from various types of basic compounds, including amines, amides, imines, carbamates, and quaternary ammonium compounds, among others, according to various embodiments. Embodiment base quenchers are described in further detail with reference to FIG. 14.

Within the solid content of the overcoat composition 20, the base quencher 204 may comprise between 0.01 wt % and 10 wt % of the total solid weight. In certain embodiments, the base quencher 204 may be incorporated into a polymer (which may be the polymer 200 or a separate polymer). In various embodiments in which the base quencher 204 is incorporated in polymeric form, it may have abundances such as those described above for the fluorine-free acid generator 22.

The organic solvent 206 may serve as a carrier medium for the other components of the overcoat composition 20, facilitating application of the overcoat composition 20 in a uniform layer over a resist pattern (such as the relief pattern 104). The organic solvent 206 may be selected to provide good solubility for the polymer 200, the fluorine-free acid generator 22, and the base quencher 204, while being compatible with underlying resist materials (such as the resist 103) to prevent unwanted dissolution of the resist pattern. The organic solvent 206 may comprise various types of solvents, including alcohols, esters, ethers, ketones, and hydrocarbons, among others, according to various embodiments. In some embodiments, the organic solvent 206 may be a solvent mixture comprising two or more solvents. In certain embodiments, the organic solvent 206 may also comprise an aqueous fraction. Embodiment solvents are described in further detail with reference to FIG. 15.

In addition to the components illustrated in FIG. 2A, the overcoat composition 20 may further include one or more optional components, in various embodiments. For example, the composition may include a surfactant to improve coating quality, which may enable filling narrow gaps between closely spaced features in an underlying relief pattern. Typical surfactants may be amphiphilic, comprising hydrophilic and hydrophobic structural components. Suitable surfactants may be ionic (anionic or cationic) or nonionic, and may include silicone surfactants, poly(alkylene oxide) surfactants, and fluorochemical surfactants, among others.

Other optional additives may include actinic and contrast dyes to improve lithographic performance (in embodiments comprising patterned acid generation rather than flood exposure, or in which subsequent lithographic patterning is desirable); anti-striation agents; plasticizers; speed enhancers; sensitizers; thermal acid generators to complement photoacid generators (or vice versa); and dissolution inhibitors, according to various embodiments. Surfactants and other optional components may be present in minor amounts, such as between 0.01 wt % and 10 wt % of a total solid weight of the overcoat composition 20, according to various embodiments.

Components of the overcoat composition 20 are now described in greater detail, according to various embodiments. FIG. 3 illustrates Schemes (P1), (P2), and (P3), which represent three types of polymerized units that may be part of the polymer 200, according to various embodiments. The polymerized units depicted may be incorporated into the polymer structure, either individually or in combination, to provide desired properties for the overcoat composition.

Scheme (P1) represents a polystyrene derivative unit having a substituted or unsubstituted phenyl ring, according to various embodiments. In Scheme (P1), each X independently represents a halogen atom that may be present at various positions on the phenyl ring, with k being an integer from 0 to 4 that indicates the number of halogen substituents.

In Scheme (P1), Q may be a single bond or a divalent linking group, connecting the phenyl ring to an organic substituent group R^{a}. According to various embodiments, a divalent linking group may comprise, for example, —O—, —S—, —Te—, —Se—, —C(O)—, —C(O)O—, —N(R)—,—C(O)N(R)-, —S(O)—, —S(O)₂—, —C(S)—, —C(Te)—, —C(Se)—, C₁-C₃₀ alkylene, C₃-C₃₀ cycloalkylene, C₃-C₃₀ heterocycloalkylene, C₆-C₃₀ arylene, C₃-C₃₀ heteroarylene, or a combination thereof, with or without further substitution of any hydrogen atoms for other monovalent organic groups.

Exemplary organic substituent groups that may be substituted for hydrogen comprise halogen, nitro (—NO₂), cyano (—CN), hydroxyl (—OH), oxo (O), amino (—NH₂), mono- or di-(C₁-C₆)alkylamino, alkanoyl (such as acyl) or formyl (—C(O)H); carboxylic acid or carboxylate salt; esters such as C₂-C₆ alkyl esters (—C(O)O-alkyl or —OC(O)-alkyl), C₇-C₁₃ aryl esters (—C(O)O-aryl or —OC(O)-aryl), acrylates, methacrylates, or lactones; amido (—C(O)NR₂, wherein R is hydrogen or C₁-C₆ alkyl); carboxamido (—CH₂C(O)NR₂, wherein R is hydrogen or C₁-C₆ alkyl); thiol (—SH), C₁-C₆ alkylthio (—S-alkyl), or thiocyano (—SCN); C₁-C₆ alkyl, C₂-C₆ alkenyl, or C₂-C₆ alkynyl; C₁-C₆ haloalkyl; C₁-C₉ alkoxy or C₁-C₆ haloalkoxy; C₃-C₁₂ cycloalkyl, C₅-C₁₈ cycloalkenyl, or C₂-C₁₈ heterocycloalkenyl; C₆-C₁₂ aryl having at least one aromatic ring (e.g., phenyl, biphenyl, naphthyl, or the like, each ring being either substituted or unsubstituted aromatic); C₇-C₁₉ arylalkyl having 1 to 3 separate or fused rings and from 6 to 18 ring carbon atoms; arylalkoxy having 1 to 3 separate or fused rings and from 6 to 18 ring carbon atoms; C₇-C₁₂ alkylaryl; C₃-C₁₂ heterocycloalkyl or C₃-C₁₂ heteroaryl; C₁-C₆ alkyl sulfonyl (—S(O)₂-alkyl); C₆-C₁₂ arylsulfonyl (—S(O)₂-aryl); tosyl (CH₃C₆H₄SO₂—); and other such organic groups.

In Scheme (P1), R^{a} may be hydrogen, a halogen atom, substituted or unsubstituted C₁-C₁₂ alkyl, or substituted or unsubstituted C₁-C₁₂ haloalkyl. According to various embodiments, Scheme (P1) may represent units derived from monomers such as styrene, 4-hydroxystyrene, 4-alkoxystyrene, or halogen-substituted variants thereof. In various embodiments, units corresponding to Scheme (P1) may provide etch resistance and thermal stability to the polymer 200, among other properties.

Examples of polymerized units corresponding to embodiments of Scheme (P1) are provided in FIG. 4A, including polystyrene 400 and poly(4-hydroxystyrene) 401. An example group of poly(4-halostyrene) units 40 is shown, though poly(4-fluorostyrene) is omitted in order to emphasize that it may be desirable to exclude fluorine in certain embodiments. An example group of 4-(alkyl or cycloalkyl)-substituted polystyrenes 41 includes methyl, ethyl, isopropyl, sec-butyl, tert-butyl, 3-pentyl, cyclopentyl, and cyclohexyl substituents. A subset of corresponding poly(4-alkoxystyrene) units 42 is shown, as is poly(4-acetoxystyrene) 403. It should be understood that FIG. 4A provides only a subset of valid embodiments of Scheme (P1), and many other variations are possible consistent with embodiments of this disclosure.

Scheme (P2) in FIG. 3 represents a poly(acrylic acid) derivative unit comprising a carboxylic acid group. In Scheme (P2), R^{b} may represent hydrogen, C₁-C₃ alkyl, or C₁-C₃ haloalkyl. In embodiments in which R^{b} is hydrogen or a methyl group, Scheme (P2) corresponds to poly(acrylic acid) (PAA) or to poly(methacrylic acid) (PMAA). The carboxylic acid functional group in Scheme (P2) may enable control over the hydrophilicity of the polymer 200 and its solubility in various developers (including the organic solvent 206), among other properties, according to embodiments.

FIG. 4B illustrates examples of polymerized units derived from Schemes (P2) and (P3), according to various embodiments. Examples illustrated include PAA 402 and PMAA 404, as well as a group of poly(alkylacrylic acid) units 43 including ethyl, isopropyl, and n-propyl substituents.

Scheme (P3) in FIG. 3 represents a polyacrylate or polyacrylamide derivative unit. According to various embodiments, W may be O (oxygen), corresponding to a polyacrylate; alternatively, W may be NR, with R being hydrogen or C₁-C₆ alkyl, corresponding to a polyacrylamide.

In Scheme (P3), R¹ represents hydrogen, a halogen atom, C₁-C₃ alkyl, or C₁-C₃ haloalkyl. The substituent R^{d} represents substituted or unsubstituted C₁-C₂₀ alkyl or substituted or unsubstituted C₁-C₂₀ heteroalkyl. According to various embodiments, Scheme (P3) may represent units derived from monomers such as methyl acrylate, methyl methacrylate, ethyl acrylate, butyl acrylate, or their acrylamide counterparts. These units may enable control over various properties of the polymer 200, such as its absorptivity at deep UV wavelengths and its adhesion to various substrates, among other properties, according to embodiments.

With further reference to FIG. 4B, example embodiments of Scheme (P3) include poly(methyl acrylate) 406, poly(methyl methacrylate) (PMMA) 407, and poly(N,N-dimethylacrylamide) (PDMA) 408. A selection of poly(alkyl acrylate) and poly(alkyl methacrylate) units 44 is shown, including poly(ethyl acrylate), poly(tert-butyl acrylate), and poly(n-butyl methacrylate). A group of acrylamides 45 includes various singly and doubly N-substituted acrylamide and methacrylamide units.

As with FIG. 4A, it should be understood that FIG. 4B provides only representative examples of valid embodiments of Schemes (P2) and (P3), and many other variations are possible consistent with embodiments of this disclosure.

In various embodiments, the polymer may include units from one, two, or all three of the schemes depicted in FIG. 3, forming homopolymers (such as those corresponding to the units of FIGS. 4A and 4B); copolymers (such as those corresponding to the copolymer units of FIG. 4C, described below); or terpolymers (such as those corresponding to the terpolymer units of FIG. 4D, also described below). In some embodiments, the polymer may comprise additional polymerized units, including types not shown in FIGS. 3-4, comprising groups such as alkyl, hydroxy, fluoroalkyl, fluoroalcohol, ester, ether, imide, sulfonamide, acid (e.g., sulfonic acid or carboxylic acid), oxoalkanoate, or combinations thereof.

FIG. 4C illustrates examples of copolymers combining units from Schemes (P1)-(P3), according to various embodiments. In addition to combinations of exemplary units from FIGS. 4A and 4B, a group 46 includes copolymers with units obtainable by reacting poly(vinyl alcohol) (PVA) with an aldehyde, such as formaldehyde or (in the example embodiments) methaldehyde or butyraldehyde.

FIG. 4C illustrates examples of terpolymers combining units from Schemes (P1)-(P3), according to various embodiments. In addition to combinations of exemplary units from FIGS. 4A and 4B, some examples include other polymerized units, such as poly(N-vinylpyrrolidone) 410, PVA 412, and poly(vinyl chloride) (PVC) 414.

As with FIGS. 4A and 4B, it should be understood that FIGS. 4C and 4D provides only representative examples of valid copolymers and terpolymers. Many other variations may be consistent with embodiments of this disclosure.

Whatever its composition, the polymer 200 may have a weight-average molecular weight (M_{w}) less than 400,000 g/mol, according to embodiments. In some embodiments, M_{w} may be between 3,000 g/mol and 50,000 g/mol, or between 3,000 g/mol and 25,000 g/mol. According to various embodiments, the polymer 200 may have a polydispersity index (PDI=ratio of M_{w} to number-averaged molecular weight Mₙ) of 3 or less. In some embodiments, the PDI may be 2 or less. In certain embodiments, the PDI may be 1.5 or less. These properties may be determined by gel permeation chromatography measurements compared with polystyrene standards.

Some embodiment polymers 200 may be commercially available, and others may be readily synthesized by various mechanisms, such as free-radical polymerization, anionic polymerization, cationic polymerization, metathesis polymerization, ring-opening polymerization (including anionic, cationic, or metathesis ring-opening polymerization), or vinylic addition, according to various embodiments. Suitable polymerization initiators may comprise, for example, 2,2′-azobisisobutyronitrile (AIBN), 2,2′-azobis(2,4-dimethylvaleronitrile), 2,2-azobis(2-methylpropionate), benzoyl peroxide, lauroyl peroxide, phosphoric acid, sulfuric acid, triflic acid, boron trifluoride, aluminum(III) chloride, titanium(IV) chloride, or tin(IV) chloride.

FIG. 5 presents Schemes (S1) through (S5), which provide anion structures that may be part of the fluorine-free acid generator 22, according to various embodiments. These schemes depict several possible embodiments of the anion 24 (including various five-membered heteroaromatic rings 222 determined by choices of a heteroatom X and an atom Y) and indicate additional substituents, including embodiment electron-withdrawing groups 230 (E groups), other organic substituents (R groups), linkers (L groups), and pendant groups that may be electron-withdrawing groups or other organic substituents (Z groups). It is to be understood that any groups depicted as bonded to the center of a ring may be substituted for any hydrogen atom of that ring, and thus that multiple arrangements of substituents may be valid embodiments of a given scheme.

According to various embodiments, Scheme (S1) represents anions 24 comprising cyclopentadienide (C₅H₄⁻, Cpide), which is a five-membered aromatic ring 222 comprising only carbon atoms and carrying a negative charge. Schemes (S2) and (S3) depict anions 24 respectively comprising indenide (C₉H₆⁻) and fluorenide (C₃H₈⁻), which may be obtained symbolically by fusing Cpide with one or two benzene rings, according to embodiments. It is to be understood that substitution with electron-withdrawing groups 230 (represented by E's in FIG. 5) or other substituents (represented by R's in FIG. 5) may reduce the numbers of hydrogens attached to the five-membered ring 222 or to a fused ring system of the corresponding anions 24, according to various embodiments.

According to various embodiments, Scheme (S4) represents anions 24 comprising a five-membered aromatic ring 222 that is heteroaromatic and substituted with at least one sulfonate as an electron-withdrawing group 230. Scheme (S5) illustrates anions 24 comprising a fused heteroaromatic sulfonate, which may be obtained symbolically by fusing Scheme (S4) with a benzene ring, in various embodiments.

These anions 24, when paired with appropriate cations 240, form fluorine-free acid generators 22 that may provide (or be) strong acids for various embodiment patterning methods. Suitable embodiment anions 24 include those whose conjugate acids have pKₐ between −15 and 10. In some embodiments comprising superacids, a conjugate acid of the anion 24 may have pKₐ between −15 and 2. In certain embodiments, a conjugate acid of the anion 24 may have pKₐ between −10 and −1.

In Schemes (S1)-(S3), E¹, E², E³, E⁴, and E⁵ are each independently an electron-withdrawing group, such as those described above with reference to FIGS. 2A and 2B. In some embodiments, each EWG may be selected independently from halogen, substituted or unsubstituted C₁-C₂₀ haloalkyl, substituted or unsubstituted C₆-C₂₀ aryl, substituted or unsubstituted C₃-C₂₀ heteroaryl, —OR⁶, —SR⁷, —NO₂, —CN, —C(O)R⁸, —C(O)OR⁹, —C(O)NR¹⁰R¹¹, —S(O)₂OR¹², —S(O)R³, —S(O)₂R¹⁴, —OS(O)₂R¹⁵, or a combination thereof.

In the electron-withdrawing groups above, R⁶ to R¹² are each independently hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl.

In the electron-withdrawing groups above, R¹³ to R¹⁵ are each independently substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl.

In some embodiments, E¹, E², E³, E⁴, and E⁵ are each independently —CN, —C(O)R⁸, —C(O)OR⁹, —S(O)R¹³, or —S(O)₂R¹⁴, wherein R⁸, R⁹, R¹³, and R¹⁴ are as defined above. In some embodiments, each of E¹ to E⁵ is free of fluorine.

In Scheme (S1), n1 is an integer from 1 to 4. In some embodiments, n1 may be 3 or 4, and in certain embodiments n1 may be 4. In some embodiments, n1 may be an integer of 3 or greater.

In Scheme (S1), m1 is an integer from 0 to 3. In some embodiments, mi is 0 or 1, and in certain embodiments m1 is 0. It is to be understood that one or more hydrogen atoms are present when m1 is 0.

In Scheme (S1), the sum n1+m1 is at least 1 because the anion is substituted with one or more electron-withdrawing groups. In some embodiments, the sum n1+m1 may be an integer from 1 to 4. In some embodiments, the sum n1+m1 is 3 or 4, and in certain embodiments the sum n1+m1 is 4.

In Scheme (S2), n2 is an integer from 0 to 4, and n3 is an integer from 0 to 2, provided that at least one of n2 and n3 is not 0. In other words, Scheme (S2) requires at least one of E² or E³ as a ring substituent. In some embodiments, n2 may be 3 or 4, and n3 may be 1 or 2. In certain embodiments, n2 may be 4, and n3 may be 2. In some embodiments, the sum n2+n3 may be an integer of 3 or greater.

In Scheme (S2), m2 is an integer from 0 to 4, and m3 is an integer from 0 to 2. In some embodiments, m2 is 0 or 1 and m3 is 0 or 1. In certain embodiments, m2 and m3 are both 0. It is to be understood that one or more hydrogen atoms are present when the sum n2+m2 is less than 4, and that one or more hydrogen atoms are present when m3 is 0.

In Scheme (S2), the sum n1+n2+m1+m2 is at least 1 because the anion is substituted with one or more electron-withdrawing groups. In some embodiments, the sum n2+m2 may be an integer from 0 to 4. In some embodiments, the sum n2+m2 is 3 or 4, and in certain embodiments the sum n2+m2 is 4. In some embodiments, the sum n3+m3 may be an integer from 0 to 2. In some embodiments, the sum n3+m3 is 1 or 2, and in certain embodiments the sum n3+m3 is 2.

In Scheme (S3), n4 and n5 are each independently an integer from 0 to 4, provided that at least one of n4 and n5 is not 0. In other words, Scheme (S3) requires at least one of E⁵ or E⁶ as a ring group substituent. In some embodiments, n4 is 3 or 4, and n5 is 3 or 4, and in certain embodiments n4 and n5 are each 4. In some embodiments, the sum n4+n5 may be an integer of 3 or greater.

In Scheme (S3), m4 and m5 are each independently an integer from 0 to 4. In some embodiments, m4 and m5 each independently may be 0 or 1, and in certain embodiments m4 and m5 each may be 0. It is to be understood that one or more hydrogen atoms are present when the sum n4+m4 is less than 4, and that one or more hydrogen atoms are present when the sum n5+m5 is less than 4. In some embodiments, the sum n4+m4 may be 4, and the sum n5+m5 may be 4.

In Scheme (S3), the sum n4+n5+m4+m5 is at least 1 because the anion is substituted with one or more electron-withdrawing groups. In some embodiments, the sum n4+m4 may be an integer from 0 to 4. In some embodiments, the sum n4+m4 is 3 or 4, and in certain embodiments the sum n4+m4 is 4. In some embodiments, the sum n5+m5 may be an integer from 0 to 4. In some embodiments, the sum n5+m5 is 3 or 4, and in certain embodiments the sum n5+m5 is 4.

In Schemes (S1)-(S3), R¹, R², R³, R⁴, and R⁵ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl.

In some embodiments, R¹, R², R³, R⁴, and R⁵ each may independently be substituted or unsubstituted C₁-C₁₀ alkyl, substituted or unsubstituted C₄-C₈ cycloalkyl, substituted or unsubstituted C₃-C₁₀ heterocycloalkyl, substituted or unsubstituted C₆-C₁₄ aryl, substituted or unsubstituted C₇-C₁₅ arylalkyl, substituted or unsubstituted C₇-Cis alkylaryl, substituted or unsubstituted C₃-C₁₀ heteroaryl, substituted or unsubstituted C₄-C₁₁ heteroarylalkyl, or substituted or unsubstituted C₄-C₁₁ alkylheteroaryl.

Each of R¹, R², R³, R⁴, and R⁵ may further comprise one or both of a divalent linking group or a polymerizable group as part of its structure. Exemplary polymerizable groups may be those including an ethylenically unsaturated double bond, such as substituted or unsubstituted C₂-C₂₀ alkenyl, or substituted or unsubstituted norbornyl. In some embodiments, polymerizable groups may include (meth)acrylate or C₂ alkenyl.

In Scheme (S1), two or more adjacent R¹ groups together may form a ring that may further comprise one or more divalent linking groups as part of its structure, wherein each of the one or more divalent linking groups is substituted or unsubstituted, and wherein the ring is substituted or unsubstituted. In some embodiments, two or more R¹ groups do not form a ring together.

In Scheme (S2), two or more adjacent R² groups together may form a ring that may further comprise one or more divalent linking groups as part of its structure, wherein each of the one or more divalent linking groups is substituted or unsubstituted, and wherein the ring is substituted or unsubstituted. In some embodiments, two or more R² groups do not form a ring together.

In Scheme (S2), two or more adjacent R³ groups together may form a ring that may further comprise one or more divalent linking groups as part of its structure, wherein each of the one or more divalent linking groups is substituted or unsubstituted, and wherein the ring is substituted or unsubstituted. In some embodiments, two or more R³ groups do not form a ring together.

In Scheme (S2), two or more adjacent R² and R³ groups together may form a ring that may further comprise one or more divalent linking groups as part of its structure, wherein each of the one or more divalent linking groups is substituted or unsubstituted, and wherein the ring is substituted or unsubstituted. In some embodiments, R² and R³ do not form a ring together.

In Scheme (S3), two or more adjacent R⁴ groups together may form a ring that may further comprise one or more divalent linking groups as part of its structure, wherein each of the one or more divalent linking groups is substituted or unsubstituted, and wherein the ring is substituted or unsubstituted. In some embodiments, two or more R⁴ groups do not form a ring together.

In Scheme (S3), two or more adjacent R⁵ groups together may form a ring that may further comprise one or more divalent linking groups as part of its structure, wherein each of the one or more divalent linking groups is substituted or unsubstituted, and wherein the ring is substituted or unsubstituted. In some embodiments, two or more R⁵ groups do not form a ring together.

In Scheme (S3), two or more adjacent R⁴ and R⁵ groups together may form a ring that may further comprise one or more divalent linking groups as part of its structure, wherein each of the one or more divalent linking groups is substituted or unsubstituted, and wherein the ring is substituted or unsubstituted. In some embodiments, R⁴ and R⁵ do not form a ring together.

In Schemes (S1)-(S3), L¹, L², and L³ are linkers that may each independently be a hydrogen, a single bond, or a divalent linking group, or any of the above groups as defined for R¹, R², R³, R⁴, and R⁵ or E¹, E², E³, E⁴, and E⁵. In Schemes (S1)-(S3), a single bond may be an open valence that bonds to another group or part of the molecule. For example, a single bond may bond to an electron-withdrawing group (any one of E¹-E⁵), to an organic substituent group (any one of R¹-R⁵), or to a carbon atom depicted explicitly in Schemes (S1)-(S3), thereby forming a ring, according to various embodiments.

Exemplary divalent linking groups for Schemes (S1)-(S3) include one or more of substituted or unsubstituted C₁-C₃₀ alkylene, substituted or unsubstituted C₄-C₃₀ cycloalkylene, substituted or unsubstituted C₃-C₃₀ heterocycloalkylene, substituted or unsubstituted C₆-C₃₀ arylene, substituted or unsubstituted C₇-C₃₀ arylalkylene, substituted or unsubstituted C₃-C₃₀ heteroarylene, substituted or unsubstituted divalent C₄-C₃₀ heteroarylalkylene, —O—, —C(O)—, and/or —C(O)O—.

In certain embodiments, L¹, L², and L³ are each independently a single bond or a divalent linking group selected from one or more of substituted or unsubstituted C₁-C₁₀ alkylene, —O—, —C(O)—, and/or —C(O)O—. In some embodiments, each of L¹, L², and L³ is free of fluorine.

In Scheme (S1), one or more R¹ groups and L¹ together may form a ring that may further comprise one or more divalent linking groups as part of its structure, wherein each of the one or more divalent linking groups is substituted or unsubstituted, and wherein the ring is substituted or unsubstituted. In some embodiments, R¹ and L¹ do not form a ring together.

In Scheme (S2), one or more R² groups and L² together may form a ring that may further comprise one or more divalent linking groups as part of its structure, wherein each of the one or more divalent linking groups is substituted or unsubstituted, and wherein the ring is substituted or unsubstituted. In some embodiments, R² and L² do not form a ring together.

In Scheme (S2), one or more R³ groups and L² together may form a ring that may further comprise one or more divalent linking groups as part of its structure, wherein each of the one or more divalent linking groups is substituted or unsubstituted, and wherein the ring is substituted or unsubstituted. In some embodiments, R³ and L² do not form a ring together.

In Scheme (S3), one or more R⁴ groups and L³ together may form a ring that may further comprise one or more divalent linking groups as part of its structure, wherein each of the one or more divalent linking groups is substituted or unsubstituted, and wherein the ring is substituted or unsubstituted. In some embodiments, R⁴ and L³ do not form a ring together.

In Scheme (S3), one or more R⁵ groups and L² together may form a ring that may further comprise one or more divalent linking groups as part of its structure, wherein each of the one or more divalent linking groups is substituted or unsubstituted, and wherein the ring is substituted or unsubstituted. In some embodiments, R⁵ and L³ do not form a ring together.

In one or more embodiments, L¹, L², and L³ may each independently be an organic group comprising a semi-metal element that may be selected from B, Si, Ge, As, Se, Te, Sb, or a combination thereof. In some embodiments, the semi-metal may be selected from B, Si, or Ge.

According to various embodiments, an anion 24 corresponding to Scheme (S1), (S2), or (S3) may include one or more —CN groups and at least one Si atom. In some embodiments, the anion may include two, three, four, or more —CN groups and at least one Si atom.

Having described Schemes (S1)-(S3) in detail, example structures are now presented with reference to FIGS. 6A-6D (for embodiment anions 24 comprising Cpide per Scheme (S1)) and FIG. 7 (for embodiment anions 24 comprising indenide per Scheme (S2) or fluorenide per Scheme (S3)).

In the example structures of FIGS. 6-7, the cyano group (—CN) serves as an exemplary electron-withdrawing group 230; it is to be understood that other EWGs may be substituted for one or more cyano groups in the example structures to produce valid embodiment anions 24. Because conventional IUPAC nomenclature for the species presented are lengthy, dicyano-, tricyano-, and tetracyano- Cpide structures are respectively referred to herein as DCpide, TCpide, and QCpide. The trimethylsilyl group (—Si(CH₃)₃) is referred to herein as TMSyl, not to be confused with tetramethylsilane.

With reference now to FIG. 6A, pentacyano Cpide 600 is a fully cyano-substituted Cpide structure. Substitution of one cyano group in pentacyano Cpide 600 yields, for example, substituted QCpides 60, including methyl QCpide, n-butyl QCpide, trimethylsilyl (TMSyl) QCpide with and without further substitution (e.g., n-butyl or phenyl) at the Si atom, and QCpide silyl ethers.

Exchanging one cyano group of pentacyano Cpide 600 with a different electron-withdrawing group, methoxycarbonyl, yields methoxycarbonyl QCpide 602. Substituted methoxycarbonyl TCpides 62 are also presented, with a similar selection of substituents to those of the substituted QCpides 60.

With reference now to FIG. 6B, exchanging one cyano group of pentacyano Cpide 600 with an organosulfur electron-withdrawing group, the phenylsulfonyl group, yields anions 24 that are also sulfones, such as phenylsulfonyl QCpide 604, with corresponding substituted phenylsulfonyl TCpides 64. Lower degrees of substitution are represented by phenylsulfonyl TMSyl DCpide 606, which has a hydrogen attached to the CPide ring. Valid embodiment sulfones may have different substitution from phenyl substitution, e.g., alkyl substitution, as in n-propylsulfonyl TMSyl DCpide 608.

As shown in FIG. 6C, exchanging one cyano group of pentacyano Cpide 600 with a different organosulfur electron-withdrawing group, the phenylsulfinyl group, yields anions 24 that are also sulfoxides, such as phenylsulfinyl QCpide 610, with corresponding substituted phenylsulfinyl TCpides 66. Lower degrees of substitution are represented by phenylsulfinyl TMSyl DCpide 612. Greater diversity of substitution is represented by a structure 614 further exchanging another cyano group of phenylsulfinyl TMSyl DCpide 612 for a formyl group.

FIG. 6D presents still other examples of embodiment anions 24 consistent with Scheme (S1), including other formyl Cpides 616, substituted tetrachloro Cpides 618, substituted tetrabromo Cpides 620, tetramethoxycarbonyl TMSyl Cpide 622, other chloro Cpides 624, and iodo Cpides 626.

Valid embodiment anions 24 may comprise two or more linked cyclopentadienide, indenide, or fluorenide rings. For example, and with further reference to FIG. 6D, substituting a methyl group in TMSyl QCpide yields corresponding tetracyano diides 628. Substituting a methyl group in methoxycarbonyl TMSyl TCpide yields corresponding methoxycarbonyl tricyano diides 630.

FIG. 7 presents examples of embodiment anions 24 consistent with Schemes (S2) and (S3), i.e., comprising indenide or fluorenide. Heptacyanoindenide 700 and nonacyanofluorenide 702 are fully cyano-substituted structures. Substitution of one cyano group in either yields, for example, substituted hexacyanoindenides 70 and substituted octacyanoindenides 72.

It is to be understood that FIGS. 6-7 provide only a selection of examples of valid embodiment anions 24 according to Schemes (S1)-(S3). For example, fusing one or two benzene rings with any of the example structures of FIGS. 6A-6D and distributing any excess substituents from the cyclopentadienide ring to the benzene ring(s) may produce additional valid embodiments of Schemes (S2) and (S3) to complement those in FIG. 7. Moreover, many other variations may be consistent with embodiments of this disclosure.

Schemes (S4) and (S5) of FIG. 5 are now described in greater detail. In Schemes (S4)-(S5), X¹ and X² are separately selected from a group consisting of S, O, and NR—wherein R is an organic substituent group as described above, and in some embodiments as described for R¹-R⁵—and Y¹ and Y² are separately selected from a group consisting of C and N. In certain embodiments, R is hydrogen or C₁-C₆ alkyl.

A corresponding five-membered aromatic ring in Scheme (S4) may be thiophene, furan, pyrrole, an N-substituted pyrrole, thiazole, oxazole, imidazole, or an N-substituted imidazole. Corresponding bicyclic heteroaromatic rings in Scheme (S5) may be benzothiophene, benzofuran (coumarone), indole, an N-substituted indole, benzothiazole, benzoxazole, benzimidazole, or an N-substituted benzimidazole.

In Schemes (S4)-(S5), each of Z¹ and Z² are selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, substituted or unsubstituted C₄-C₂₀ heteroarylalkyl, or an electron-withdrawing group as defined below, provided that when Y¹ or Y² is N, Z¹ or Z² is respectively not present in the structure.

In Schemes (S4)-(S5), E⁶ and E⁷ are each independently an electron-withdrawing group, as described above with reference to the fluorine-free acid generator 22 of FIGS. 2A and 2B. In some embodiments, each electron-withdrawing group independently may be selected from halogen, substituted or unsubstituted C₁-C₂₀ haloalkyl, substituted or unsubstituted C₆-C₂₀ aryl, substituted or unsubstituted C₃-C₂₀ heteroaryl, —OR¹⁸, —SR¹⁹, —NO₂, —CN, —C(O)R²⁰, —C(O)OR²¹, —C(O)NR²²R²³, —S(O)₂OR²⁴, —S(O)R²⁵, —S(O)₂R²⁶, —OS(O)₂R²⁷, or a combination thereof.

In the electron-withdrawing groups above, R¹⁸-R²⁷ are each independently hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl.

In some embodiments, E⁶ and E⁷ are each independently —CN, —C(O)R²⁰, —C(O)OR²¹, —S(O)R²⁵, or —S(O)₂R²⁶, wherein R²⁰, R²¹, R²⁵, and R²⁶ are as defined herein. In some embodiments, each of E⁶ and E⁷ is free of fluorine.

In Scheme (S4), n6 is an integer from 0 to 2. In some embodiments, n6 may be 1 or 2, and in certain embodiments n6 may be 2.

In Scheme (S4), m6 is an integer from 0 to 2. In some embodiments, m6 is 0 or 1, and in certain embodiments m6 is 0. It is to be understood that one or more hydrogen atoms are present when m6 is 0.

In Scheme (S4), the sum n6+m6 is at least 1 because the anion is substituted with one or more electron-withdrawing groups. In some embodiments, the sum n6+m6 may be an integer from 1 to 2.

In Scheme (S5), n7 is an integer from 1 to 4. In other words, Scheme (S5) requires at least one of E⁷ as a ring group substituent. In some embodiments, n7 may be 3 or 4, and in certain embodiments n7 may be 4.

In Scheme (S5), m7 is an integer from 0 to 2. In some embodiments, m7 is 0 or 1. It is to be understood that one or more hydrogen atoms are present when the sum n7+m7 is less than 2.

In Schemes (S4)-(S5), R¹⁶ and R¹⁷ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl.

In some embodiments, R¹⁶ and R¹⁷ each may independently be substituted or unsubstituted C₁-C₁₀ alkyl, substituted or unsubstituted C₄-C₈ cycloalkyl, substituted or unsubstituted C₃-C₁₀ heterocycloalkyl, substituted or unsubstituted C₆-C₁₄ aryl, substituted or unsubstituted C₇-C₁₅ arylalkyl, substituted or unsubstituted C₇-C₁₅ alkylaryl, substituted or unsubstituted C₃-C₁₀ heteroaryl, substituted or unsubstituted C₄-C₁₁ heteroarylalkyl, or substituted or unsubstituted C₄-C₁₁ alkylheteroaryl.

Each of R¹⁶ and R¹⁷ may further comprise one or both of a divalent linking group or a polymerizable group as part of its structure. Exemplary polymerizable groups may be those including an ethylenically unsaturated double bond, such as substituted or unsubstituted C₂-C₂₀ alkenyl or substituted or unsubstituted norbornyl. In some embodiments, polymerizable groups may include (meth)acrylate or C₂ alkenyl.

In Scheme (S4), two or more adjacent R¹⁶ groups together may form a ring that may further comprise one or more divalent linking groups as part of its structure, wherein each of the one or more divalent linking groups is substituted or unsubstituted, and wherein the ring is substituted or unsubstituted. In some embodiments, two or more R¹⁶ groups do not form a ring together.

In Scheme (S5), two or more adjacent R¹⁷ groups together may form a ring that may further comprise one or more divalent linking groups as part of its structure, wherein each of the one or more divalent linking groups is substituted or unsubstituted, and wherein the ring is substituted or unsubstituted. In some embodiments, two or more R¹⁷ groups do not form a ring together.

Having described Schemes (S4) and (S5) in detail, example structures are now presented with reference to FIG. 8A (for embodiment anions 24 comprising heteroaromatic sulfonate per Scheme (S4)) and to FIG. 8B (for embodiment anions 24 comprising fused heteroaromatic sulfonate per Scheme (S5)).

In the example structures of FIGS. 8A and 8B, the cyano group (—CN) and the nitro group (—NO₂) serves as exemplary electron-withdrawing groups 230; it is to be understood that other EWGs may be substituted for one or more of these groups in the example structures to produce valid embodiment anions 24. Similarly, the methyl group (Me=—CH₃) may be an exemplary substituent that may be substituted for a valid R¹⁶ or R¹⁷ in the respective structures.

FIG. 8A shows four heteroaromatic sulfonates consistent with embodiments of Scheme (S4): furan-2-sulfonate 800, oxazole-2-sulfonate 802, thiophene-2-sulfonate 804, and thiazole-2-sulfonate 806. While pyrrole-2-sulfonate, imidazole-2-sulfonate, and their N-substituted variants are not shown in FIG. 8A, such structures may be obtained symbolically by replacing (for example) the O in furan-2-sulfonate 800 and oxazole-2-sulfonate 802 with NH or NR.

In FIG. 8A, a set 80 of cyano- or nitro-substituted heteroaromatic sulfonates is presented. Substitution of the set 80 with an additional electron-withdrawing group, such as cyano, nitro, halo (chloro or bromo), or acetyl, yields a set 82; substitution of the set 80 with a methyl substituent yields a set 84.

FIG. 8B shows four fused heteroaromatic sulfonates consistent with embodiments of Scheme (S5): benzofuran-2-sulfonate (coumarone-2-sulfonate) 808, benzoxazole-2-sulfonate 810, benzothiophene-2-sulfonate 812, and thiazole-2-sulfonate 814. While indole-2-sulfonate, benzimidazole-2-sulfonate, and their N-substituted variants are not shown in FIG. 8B, such structures may be obtained symbolically by replacing (for example) the O in benzofuran-2-sulfonate 808 and benzoxazole-2-sulfonate 810 with NH or NR.

In FIG. 8B, a set 86 of fused heteroaromatic sulfonates with cyano substitution on the benzene ring is presented. Benzofuran-2-sulfonate 808 and benzothiophene-2-sulfonate 812 may also permit substitution on the five-membered aromatic ring, as depicted in a set 87. Substitution of the set 86 or the set 87 with an additional electron-withdrawing group, such as the exemplary cyano group, yields a set 88 or a set 89, respectively.

It is to be understood that FIGS. 8A and 8B provide only a selection of examples of valid embodiment anions 24 according to Schemes (S4) and (S5). For example, sulfonates in which the —SO₃⁻ is substituted at a position of the respective heteroaromatic or fused heteroaromatic ring system other than the illustrated position may produce additional valid embodiments of Schemes (S4) or (S5). For another example, fusing a benzene ring with any of the example structures of FIG. 8A and distributing any excess substituents from the heteroaromatic ring to the benzene ring may produce additional valid embodiments of Scheme (S5) to complement those in FIG. 8B. Moreover, many other variations may be consistent with embodiments of this disclosure.

FIG. 9 presents Schemes (S6)-(S8), which provide cation structures that may be part of the fluorine-free acid generator 22, according to various embodiments. In some embodiments, the cation 240 may be an organic cation, such as a sulfonium cation (S6), an iodonium cation (S7), or a cation consistent with Scheme (S8), which represents a monoprotonated form of a nitrogen-containing base B. Specific structures corresponding to Schemes (S6)-(S8) may be determined by choices of organic substituents (R groups) or the base B.

In other embodiments not illustrated herein, the cation 240 may be a phosphonium cation (HPR₃⁺), symbolically obtained by replacing S with PH in Scheme (S6) and related exemplary structures in FIG. 10A. Other embodiment cations 240 may comprise a proton or a metal cation (such as an alkali metal cation) compatible with the desired semiconductor process flow.

In Schemes (S6) and (S7) of FIG. 9, R²-R³² are each independently substituted or unsubstituted C₁-C₂₀ alkyl, substituted or unsubstituted C₄-C₂₀ cycloalkyl, substituted or unsubstituted C₂-C₂₀ alkenyl, substituted or unsubstituted C₆-C₃₀ aryl, substituted or unsubstituted C₃-C₃₀ heteroaryl, substituted or unsubstituted C₇-C₂₀ arylalkyl, or substituted or unsubstituted C₄-C₂₀ heteroarylalkyl, or combinations thereof. Each of R²⁸-R³² may be either separate or connected to another group R²⁸-R³² via a single bond or a divalent linking group to form a ring. Each of R²⁸-R³² may include as part of its structure a divalent linking group. Each of R²⁸-R³² independently may comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

With reference to FIG. 10A, embodiment cations 240 consistent with Scheme (S6) may comprise triphenylsulfonium 1000 or other triaryl and triheteroaryl sulfonium cations, with or without substitution. Heterocyclic sulfonium cations symbolically obtained by connecting a pair of groups R²⁸-R³⁰ may comprise, for example, 4-tert-butylphenyl heterocyclic sulfoniums depicted in a set 1002. Dibenzoheterocyclic sulfonium cations symbolically obtained by linking phenyl substituents of triphenylsulfonium 1000 with a divalent linking group are depicted in a set 1004. And aryl-substituted dibenzothiophenium cations obtained by linking phenyl substituents of triarylsulfonium cations with a single bond are depicted in a set 1006, one such cation being phenyldibenzothiophenium 1007.

With reference to FIG. 10B, embodiment cations 240 consistent with Scheme (S7) may comprise diphenyliodonium 1008 or other diaryl, diheteroaryl, or dicycloalkyl iodonium cations, with or without substitution. Heterocyclic iodonium cations symbolically obtained by connecting a pair of groups R³¹ and R³² by linking phenyl substituents of diphenyliodonium 1008 with a divalent linking group are depicted in a set 1010.

It is to be understood that FIGS. 10A and 10B provide only a selection of examples of valid embodiment cations 240 according to Schemes (S6) and (S7). Many other variations may be consistent with embodiments of this disclosure.

With further reference to FIG. 9, suitable nitrogen-containing bases B in embodiments of Scheme (S8) may comprise amines such as C₁-C₂₀ alkyl amines, and C₃-C₂₀ aryl amines, with or without substitution, according to various embodiments. The foregoing nitrogen-containing bases B may be substituted, for example, with one or more group chosen from alkyl, aryl, halogen (in some embodiments fluorine), cyano, nitro and alkoxy. In some embodiments, base B may be a heteroaromatic base.

In certain embodiments, the nitrogen-containing base B may comprise ammonia (NH₃), difluoromethylamine (NH₂CHF₂), 2,2,2-trifluoroethylamine (NH₂CH₂CF₃), trimethylamine (N(CH₃)₃), triethylamine (N(CH₂CH₃)₃), N,N-dimethylethylamine (N(CH₃)₂(CH₂CH₃)).

In some embodiments, base B has a boiling point less than 170° C. In certain embodiments, base B has a boiling point less than 160° C., 150° C., 140° C., 130° C., 120° C., 110° C., 100° C., or 90° C. In certain such embodiments, a trigger temperature for activation of a fluorine-free acid generator 22 may correlate with the boiling point of base B. In these and other embodiments, a lower boiling point of base B may enable the base B to be driven off more efficiently from a substrate (such as substrate 102) during a post-exposure bake or diffusion bake.

In some embodiments, base B may have a conjugate acid (BH)⁺ that has pKₐ between 0 and 6, as determined in aqueous solution at or near room temperature. In certain embodiments, base B may have a conjugate acid (BH)⁺ that has pKₐ between 0 and 5, between 0 and 4, between 0 and 3, or between 1 and 3, according to embodiments.

In certain embodiments, cations 240 consistent with Scheme (S8) may comprise ammonium (NH₄⁺), difluoromethylaminium (HNH₂CHF₂⁺), 2,2,2-trifluoroethylaminium (HNH₂CH₂CF₃⁺), trimethylaminium (HN(CH₃)₃⁺), triethylaminium (HN(CH₂CH₃)₃⁺), or N,N-dimethylethylaminium (HN(CH₃)₂(CH₂CH₃)⁺).

Additional exemplary cations 240 consistent with Scheme (S8) are illustrated in FIG. 11, in which Y represents an alkyl group. In certain embodiments, Y may be methyl (Me=—CH₃) or ethyl (Et=—CH₂CH₃).

With further reference to FIG. 11, cations 240 consistent with Scheme (S8) may further comprise pyridinium 1100; fluorinated pyridiniums 1102; pyrazinium 1104; alkyl-substituted pyraziniums 1106; pyrimidinium 1108; fluoro- or alkyl-substituted pyrimidiniums 1110; oxazolinium 1112; alkyl-substituted oxazoliniums 1114; thiazolinium 1116; alkyl-substituted thiazoliniums 1118; oxazolium 1120; thiazolium 1122; or quinoxalium 1124, according to various embodiments.

It is to be understood that FIG. 11 provides only a selection of examples of valid embodiment cations 240 according to Scheme (S8). For example, similar substitutions as illustrated in FIG. 11 for oxazolinium 1112 and thiazolinium 1116 may yield valid embodiment cations 240 when applied to oxazolium 1120 and thiazolium 1122. Many other variations may be consistent with embodiments of this disclosure.

As described above with reference to FIG. 2A, the fluorine-free acid generator 22 may comprise a nonionic structure. According to various embodiments, FIG. 12 thus presents Schemes (S9) and (S10). These schemes depict several possible embodiments of the nonionic structure (including various five-membered heteroaromatic rings 222 determined by choices of a heteroatom X and an atom Y) and indicate additional substituents, including embodiment electron-withdrawing groups 230 (E groups), other organic substituents (R groups), linkers (L groups), and pendant groups that may be electron-withdrawing groups or other organic substituents (Z groups). It is to be understood that any groups depicted as bonded to the center of a ring may be substituted for any hydrogen atom of that ring, and thus that multiple arrangements of substituents may be valid embodiments of a given scheme.

In various embodiments, Schemes (S9) and (S10) represents a nonionic structure comprising a five-membered aromatic ring 222 that is heteroaromatic and substituted with at least one electron-withdrawing group 230 comprising an —S(O)₂— divalent linker and an additional linker L⁴ or L⁵. Scheme (S10) represents similar nonionic structures comprising a fused heteroaromatic ring system, which may be obtained symbolically by fusing Scheme (S9) with a benzene ring, in various embodiments.

In some embodiments, an EWG 230 comprising the —S(O)₂— divalent linker may be, for example, a sulfone (L¹ or L⁵=a single bond), a sulfonic ester (L¹ or L⁵=O), a thiosulfonate (L⁴ or L⁵=S), or a sulfonamide (L⁴ or L⁵=NR).

In Schemes (S9) and (S10), X³ and X⁴ are separately selected from a group consisting of S, O and NR—wherein R is an organic substituent group as described above, and in some embodiments as described for R¹-R⁵—and Y³ and Y⁴ are separately selected from a group consisting of C and N. In certain embodiments, R is hydrogen or C₁-C₆ alkyl.

Corresponding five-membered aromatic rings 222 consistent with Scheme (S9) may thus be thiophene, furan, pyrrole, an N-substituted pyrrole, thiazole, oxazole, imidazole, or an N-substituted imidazole. Corresponding bicyclic heteroaromatic rings in Scheme (S10) may be benzothiophene, benzofuran (coumarone), indole, an N-substituted indole, benzothiazole, benzoxazole, benzimidazole, or an N-substituted benzimidazole.

In Schemes (S9)-(S10), each of Z³ and Z⁴ are selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or an electron-withdrawing group as defined above for Schemes (S4) and (S5), provided that when Y³ or Y⁴ is N, Z³ or Z⁴ is respectively not present in the structure.

In Schemes (S9)-(S10), E⁸ and E⁹ are each independently an electron-withdrawing group, as defined above for Schemes (S4) and (S5). In some embodiments, each of E⁸ and E⁹ is free of fluorine.

In Scheme (S9), n8 is an integer from 0 to 2. In some embodiments, n8 may be 1 or 2, and in certain embodiments n8 may be 2.

In Scheme (S9), m8 is an integer from 0 to 2. In some embodiments, m8 is 0 or 1, and in certain embodiments m8 is 0. It is to be understood that one or more hydrogen atoms are present when m8 is 0.

In Scheme (S9), the sum n8+m8 is at least 1, because the compound is substituted with one or more electron-withdrawing groups.

In Scheme (S10), n9 is an integer from 1 to 4. In other words, Scheme (S10) requires at least one of E⁹ as a ring group substituent. In some embodiments, n9 may be 3 or 4, and in certain embodiments n9 may be 4.

In Scheme (S10), m9 is an integer from 0 to 4. In some embodiments, m9 is 0 or 1. It is to be understood that one or more hydrogen atoms are present when the sum n9+m9 is less than 4.

In Schemes (S9)-(S10), R³³-R³⁶ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl.

In some embodiments, R³³-R³⁶ each may independently be substituted or unsubstituted C₁-C₁₀ alkyl, substituted or unsubstituted C₄-C₈ cycloalkyl, substituted or unsubstituted C₃-C₁₀ heterocycloalkyl, substituted or unsubstituted C₆-C₁₄ aryl, substituted or unsubstituted C₇-C₁₅ arylalkyl, substituted or unsubstituted C₇-Cis alkylaryl, substituted or unsubstituted C₃-C₁₀ heteroaryl, substituted or unsubstituted C₄-C₁₁ heteroarylalkyl, or substituted or unsubstituted C₄-C₁₁ alkylheteroaryl.

Each of R³³-R³⁶ may further comprise one or both of a divalent linking group or a polymerizable group as part of its structure. Exemplary polymerizable groups may be those including an ethylenically unsaturated double bond, such as substituted or unsubstituted C₂-C₂₀ alkenyl, or substituted or unsubstituted norbornyl. In some embodiments, polymerizable groups may include (meth)acrylate or C₂ alkenyl.

In Schemes (S9)-(10), L⁴ and L⁵ are each independently a single bond or a divalent linking group such as O, S, or NR—wherein R is an organic substituent group as described above, and in some embodiments as described for R¹-R⁵. In certain embodiments, R is hydrogen or C₁-C₆ alkyl.

FIG. 13 depicts four heteroaromatic sulfonic esters consistent with embodiments of Scheme (S9): furan-2-yl 4-nitrobenzylsulfonate 1300, oxazol-2-yl 4-nitrobenzylsulfonate 1302, thiophen-2-yl 4-nitrobenzylsulfonate 1304, and thiazol-2-yl 4-nitrobenzylsulfonate 1306. While pyrrol-2-yl 4-nitrobenzylsulfonate, imidazol-2-yl 4-nitrobenzylsulfonate, and their N-substituted variants are not shown in FIG. 13, such structures may be obtained symbolically by replacing (for example) the O in furan-2-yl 4-nitrobenzylsulfonate 1300 and oxazol-2-yl 4-nitrobenzylsulfonate 1302 with NH or NR.

FIG. 13 further depicts sulfonic esters derived from those just described by single or double substitution of the heteroaromatic ring with exemplary cyano groups, corresponding respectively to a set 1308 or a set 1310. Furan-2-yl 4-nitrobenzylsulfonate 1300 and thiophen-2-yl 4-nitrobenzylsulfonate 1304 may also permit three cyano groups on the five-membered aromatic ring, as depicted in a set 1312. Substitution of the set 1308 with an additional electron-withdrawing group, such as the exemplary nitro group, yields a set.

It is to be understood that FIG. 13 provides only a selection of examples of valid embodiments according to Scheme (S9). For example, substitution of —O— in the sulfonic esters depicted for a single bond, —S—, or —NR— may yield corresponding sulfones, thiosulfonates, or sulfonamides, according to embodiments. For another example, fusing a benzene ring with any of the example structures of FIG. 13 and distributing any excess substituents from the heteroaromatic ring to the benzene ring may produce valid embodiments of Scheme (S10). For yet another example, embodiments in which the organosulfur group is substituted at a position other than the 2 position of the respective heteroaromatic or fused heteroaromatic ring system may produce additional valid embodiments of Schemes (S9) or (S10). Many other variations may be consistent with embodiments of this disclosure.

With further reference to FIG. 2A, embodiment base quenchers 204 are now described. The base quencher 204 may comprise a hydroxide, a carboxylate, an amine, an imine, an amide, a piperidine, and combinations thereof. In various embodiments, the base quencher 204 may comprise an ammonium salt with a hydroxide ion or a weak base, a C₁-C₃₀ quaternary alkylammonium salt with a hydroxide ion or a weak base, a C₁-C₃₀ amine, a C₁-C₃₀ amide, or a C₁-C₃₀ imine.

Ammonium-derived base quenchers 204 may comprise ammonium carbonate, ammonium hydroxide, ammonium hydrogen phosphate, ammonium phosphate, tetramethylammonium carbonate, tetramethylammonium hydroxide (TMAH), tetramethyl ammonium hydrogen phosphate, tetramethylammonium phosphate, tetraethyl ammonium carbonate, tetraethylammonium hydroxide, tetraethylammonium hydrogen phosphate, tetraethylammonium phosphate, tetrabutylammonium hydroxide, tetrabutylammonium lactate, or combinations thereof, according to various embodiments.

Amine-derived base quenchers 204 may comprise amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane; Trager's base; hindered amines, such as 1,8-diazabicyclo[5.4.0]undec-7-ene (DBU) or 1,5-diazabicyclo[4.3.0]non-5-ene (DBN); or combinations thereof, according to various embodiments.

Hydroxyamine-derived base quenchers 204 may comprise one or more C₁-C₈ hydroxyalkyl groups, in some embodiments, and in certain embodiments may comprise one or more C₁-C₅. Specific examples may include mono-, di- and tri-ethanolamine; 3-amino-1-propanol; 2-amino-2-methyl-1-propanol; 2-amino-2-ethyl-1,3-propanediol; tris(hydroxymethyl)aminomethane; N-methylethanolamine; 2-diethylamino-2-methyl-1-propanol; or combinations thereof.

Amide-derived base quenchers 204 may comprise tert-butyl N-[2-hydroxy-1,1-bis(hydroxymethyl)-ethyl]carbamate, tert-butyl 4-hydroxypiperidine-1-carboxylate, or combinations thereof, according to embodiments.

In some embodiments, the base quencher 204 may be a photodecomposable quencher (PDQ) that generates a weak acid upon irradiation. The weak acid generated from a PDQ is generally not strong enough to react rapidly or to a significant degree with acid-labile groups that may be present in resist materials. The PDQ may, however, exchange anions with stronger acids, such as those generated by the fluorine-free acid generator 22, and thus reduce the mean free path of acid in resist materials such as the overcoat 106. In embodiments comprising an ionic PDQ and an ionic fluorine-free acid generator 22, the PDQ may be chosen such that ion exchange is suppressed or has a limited effect on properties such as solubility of the PAG or PDQ, quantum yield of acid or weak acid, and diffusion rate of acid or weak acid.

PDQs may comprise photodecomposable cations such as the sulfonium, iodonium, or phosphonium cations described above with reference to FIGS. 9 and 10. The photodecomposable cation of a PDQ may be paired with a conjugate base A⁻ of a weak acid HA with pKₐ greater than 1, such as a carboxylate anion conjugate to a C₁-C₂₀ carboxylic acid, a sulfonate anion conjugate to a C₁-C₂₀ sulfonic acid, or an oxide anion conjugate to a C₁-C₂₀ alcohol.

Conjugate bases suitable for a base quencher 204 comprising a PDQ may comprise formate, acetate, propionate, bitartrate, succinate, cyclohexanecarboxylate, benzoate, salicylate, p-toluenesulfonate, 10-camphorsulfonate, and phenolate, according to various embodiments. In some embodiments, the base quencher 204 may be a zwitterionic PDQ such as diphenyliodonium-2-carboxylate.

FIG. 14 illustrates several embodiment base quenchers 204, namely TMAH 1402, tetrabutylammonium lactate 1404, DBU 1406, 1-piperidineethanol 1408, triethanolamine 1410, 1-tert-butoxycarbonyl-4-hydroxypiperidine 1411, tert-butyl N-[2-hydroxy-1,1-bis(hydroxymethyl)-ethyl]carbamate 1412, triphenylsulfonium phenolate 1413, triphenylsulfonium 10-camphorsulfonate 1414, and phenyldibenzothiophenium phenolate 1416.

With continued reference to FIG. 2A, embodiment organic solvents 206 are now described. The organic solvent 206 may include greater than 50 wt % organic liquids based on total solvent weight in the overcoat composition 20, according to various embodiments, with the remaining solvent weight comprising water or another non-organic solvent. In some embodiments, the organic solvent 206 may include greater than 90 wt %, greater than 95 wt %, or greater than 99 wt % organic liquids. In certain embodiments, the organic solvent 206 may be strictly organic, with 100 wt % organic liquids.

In various embodiments, the organic solvent 206 may comprise a C₄-C₈ monohydric alcohol (i.e., an alcohol with a single hydroxide group), a C₄-C₁₀ alkyl ester, a C₆-C₁₆ alkyl monoether (i.e., an ether with a single ether oxygen), or a C₆-C₁₆ aromatic monoether.

Embodiment alkyl monoether solvents may comprise 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, dioctyl ether, or a combination thereof, according to some embodiments. In certain embodiments, the organic solvent 206 may comprise diisoamyl ether.

Embodiment aromatic monoether solvents may comprise anisole, ethylbenzyl ether, diphenyl ether, dibenzyl ether, phenetole, or a combination thereof, according to some embodiments. In certain embodiments, the organic solvent 206 may comprise anisole.

Embodiment alcohol solvents may comprise straight, branched, or cyclic C₄-C₈ monohydric alcohols such as 1-butanol, 2-butanol, isobutyl alcohol, tert-butyl alcohol, 1-methoxy-2-propanol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, or a combination thereof, according to some embodiments. In certain embodiments, the organic solvent 206 may comprise 1-butanol or 4-methyl-2-pentanol (methyl isobutyl carbinol, MIBC).

Embodiment ester solvents may comprise alkyl propionates, such as n-butyl propionate, n-pentyl propionate, n-hexyl propionate, or n-heptyl propionate; substituted or unsubstituted alkyl acetates, such as 1-methoxy-2-propanol acetate or n-butyl acetate; alkyl butyrates, such as n-butyl butyrate, isobutyl butyrate, or isobutyl isobutyrate; lactones, such as γ-butyrolactone or γ-valerolactone; or a combination thereof, according to some embodiments. In certain embodiments, the organic solvent 206 may comprise n-butyl acetate, isobutyl isobutyrate, or γ-butyrolactone.

In various embodiments, the organic solvent 206 may further comprise other organic solvents chosen from ketones (such as 2-heptanone, 2,5-dimethyl-4-hexanone or 2,6-dimethyl-4-heptanone); hydrocarbons (such as n-heptane, n-nonane, n-octane, n-decane, 2-methylheptane, 3-methylheptane, 3,3-dimethylhexane, or 2,3,4-trimethylpentane); diethers (such as dipropylene glycol monomethyl ether); or a combination thereof. In certain embodiments, the organic solvent 206 may comprise 2-heptanone or n-decane.

According to various embodiments, the organic solvent 206 may comprise a mixture of monoether solvent, alcohol solvent, ester solvent, or other organic solvents. In some embodiments, monoether and hydrocarbon solvents may contribute a combined amount between 70 wt % and 100 wt % of the total solvent weight in the overcoat composition 20, with any alcohol or ester solvents contributing a combined amount between 2 wt % and 30 wt % of the total solvent weight. Additional organic solvents may contribute a combined amount between 1 wt % and 20 wt % of the total solvent weight, in certain embodiments.

In some embodiments, alcohol, ketone, and lactone solvents may contribute a combined amount between 70 wt % and 100 wt % of the total solvent weight in the overcoat composition 20, with any ether or hydrocarbon solvents contributing a combined amount between 2 wt % and 30 wt % of the total solvent weight. Additional organic solvents may contribute a combined amount between 1 wt % and 20 wt % of the total solvent weight, in certain embodiments.

FIG. 15 illustrates several embodiment organic solvents 206, namely diisoamyl ether 1502, anisole 1504, 1-butanol 1506, MIBC 1508, n-butyl acetate 1509, isobutyl isobutyrate 1510, 7-butyrolactone 1511, n-decane 1512, and 2-heptanone 1513.

Fluorine-free acid generators 22 such as those described above with reference to FIGS. 5-13 may enable other methods of patterning a substrate, such as those illustrated by process flows in FIGS. 16-19. These methods comprise the use of a solubility-shifting agent to form solubility-shifted regions in a target resist that may underlie or be coated over the solubility-shifting agent, according to various embodiments. The solubility-shifting agent may supply acid to the target resist, in the form of the fluorine-free acid generator 22 or acid species produced by activating the fluorine-free acid generator 22.

In various embodiments, the solubility-shifting agent may comprise an embodiment overcoat composition 20 as described above. In some embodiments, the solubility-shifting agent may have a composition similar to the overcoat composition 20, but modified to promote efficient diffusion of the fluorine-free acid generator 22 or the associated acid into a target resist. Thus, the solubility-shifting agent may comprise, in certain embodiments, relatively higher amounts of the fluorine-free acid generator 22 or embodiment acid generators with relatively higher pKₐ. In certain embodiments, the solubility-shifting agent may omit the base quencher 204 entirely, such that it is not an overcoat composition 20.

In some embodiments, the solubility-shifting agent may be applied as a thin coating on a relief pattern comprising the target resist, or a thin conformal layer over a substrate. In some embodiments, the solubility-shifting agent may thus contain a surfactant or other agents tending to promote wetting or adhesion to the target resist or to the substrate, or tending to adjust the conformality or planarity of the coating. In these and other embodiments, a thickness of the solubility-shifting agent may be between 5 nm and 150 nm; in certain embodiments, the thickness of the solubility-shifting agent may be between 5 nm and 10 nm, between 10 nm and 20 nm, between 20 nm and 30 nm, between 20 nm and 40 nm, between 20 nm and 50 nm, between 20 nm and 75 nm, or between 20 nm and 100 nm.

In some embodiments, the solubility-shifting agent may be absorbed into the target resist as part of the process of supplying acid. In some embodiments, excess or residual amounts of the thin coating or the thin conformal layer of the solubility-shifting agent may be removed with a rinse, such as an organic solvent rinse. The organic solvent used in rinsing excess or residual solubility-shifting agent may be selected not to remove any solubility-shifting agent that has been absorbed or infused into the target resist. In certain embodiments, the organic solvent may further be selected not to remove any solubility-shifted region that may be formed in the target resist. In some such embodiments, the organic solvent of the solubility-shifting agent may be used in rinsing the excess or residue.

In other embodiments, the solubility-shifting agent may be developed in tandem with the target resist. As such, and in various embodiments, the polymer and the organic solvent of the solubility-shifting agent may be selected for compatibility with the target resist. In certain embodiments, the solubility-shifting agent may be further tailored to be selective for supplying acid to the target resist in preference to a spectator resist.

FIG. 16A depicts an initial stage of patterning a substrate according to various embodiments, and in particular depicts a relief pattern 1604 provided on a substrate 1602. The substrate 1602 may be a substrate as described for substrate 102; the relief pattern 1604 may comprise a first resist 1603 patterned through photolithographic processes; and the relief pattern 1604 and resist 1603 may be as described for the relief pattern 104 and the resist 103, according to various embodiments.

FIG. 16B depicts coating of a solubility-shifting agent 1605 onto the relief pattern 1604, according to various embodiments. In some embodiments, and as illustrated, the solubility-shifting agent 1605 may be applied as a thin coating to the relief pattern 1604. In other embodiments, the solubility-shifting agent may be applied to the entire workpiece in a thin, conformal or planarizing layer. In various embodiments, the solubility-shifting agent may be coated by spin coating, vapor deposition, or other such processes. In some embodiments, a post-application bake may help to set the solubility-shifting agent 1605 and drive off residual solvent. In some embodiments, excess solubility-shifting agent between features of the relief pattern 1604 may be removed subsequently by means of a rinse.

In FIG. 16C, a second resist 1608 is formed over the relief pattern 1604 and the solubility-shifting agent 1605, by any suitable coating or deposition method, according to embodiments. In the illustrated embodiments, the second resist 1608 may be a target resist of the solubility-shifting agent 1605, and the first resist 1603 may be a spectator resist.

The solubility-shifting agent 1605 comprises a fluorine-free acid generator, such as any of those described above with reference to FIGS. 5-13. The fluorine-free acid generator 22 in the solubility-shifting agent 1605 may be a strong acid or superacid generating free acid (protons, H⁺); a photoacid generator (PAG); a thermal acid generator (TAG); or an acid generator having sensitivity to both light and heat, according to various embodiments. When activated by an appropriate stimulus (light, heat, or both, in the respective embodiments), the fluorine-free acid generator 22 may produce a plurality of acid species within the solubility-shifting agent 1605.

FIG. 16D depicts formation of a solubility-shifted region 1606 disposed between the first resist 1603 and the second resist 1608. In various embodiments, the solubility-shifted region 1606 may be formed by photochemical activation (e.g., exposure to DUV with or without a mask) or thermal activation (e.g., heating above ambient temperature for a strong acid or superacid, or above a trigger temperature for a PAG) of the fluorine-free acid generator of the solubility-shifting agent 1605. In some embodiments, a temperature for tuning acid dissociation or a trigger temperature of a thermal acid generator comprising the fluorine-free acid generator 22 may be between 50° C. and 160° C.

In some embodiments, the fluorine-free acid generator of the solubility-shifting agent 1605 may be diffused into the second resist 1608 directly, before or after activation. In certain embodiments, though not as illustrated, diffusion of the fluorine-free acid generator may be accompanied by absorption of the solubility-shifting agent 1605 into the second resist 1608.

In various embodiments, the diffusion may be carried out or promoted by a post-exposure bake or a diffusion bake. According to various embodiments, the diffusion bake may be performed at a temperature between 50° C. and 150° C. According to various embodiments, the diffusion bake may be performed for a duration between 30 s and 90 s, or for any duration producing a desired diffusion distance of the fluorine-free acid generator or acid species into the second resist 1608.

In FIG. 16D, the solubility-shifted region 1606 is disposed between the first resist 1603 and the second resist 1608. The solubility-shifted region 1606 may be formed by acid generated by the fluorine-free acid generator reacting with components of the second resist 1608, for example, by cleaving acid-labile protecting groups in the polymer of the second resist 1608. According to various embodiments, cleavage of acid-labile groups and other acid reactions shift the solubility characteristics of the affected region of the second resist 1608, making them soluble in developers that would not dissolve the unaffected portions of the resist 1608. In some embodiments, developer solvents suitable for dissolving the solubility-shifted region 1606 may comprise an organic solvent of the solubility-shifting agent 1605.

A thickness of the solubility-shifted region 1606 corresponds to a diffusion depth of acid generated from the fluorine-free acid generator into the second resist 1608. In some embodiments, the solubility-shifted region 1606 extends into the second resist 1608 to a depth between 5 nm and 60 nm. For example, in various embodiments, the thickness of the solubility-shifted region 1606 may range between a lower limit of 5, 10, 15, 20, or 25 nm and an upper limit of 40, 45, 50, 55, or 60 nm, where any lower limit may be paired with any mathematically compatible upper limit.

In some embodiments, the thickness of the solubility-shifted region 1606 may be tuned to correspond to a desired width of a line to be patterned into the substrate 1602. In other embodiments comprising line cutting, the thickness of the solubility-shifted region 1606 may be tuned to match a desired critical dimension of the cut (or break) to be made in a line or feature.

In FIG. 16E, the solubility-shifted region 1606 is developed, forming openings 1610 that expose portions of the substrate 1602. Further, and according to embodiments, the openings 1610 are disposed between the relief pattern 1604 and the second resist 1608, such that the relief pattern 1604 and the second resist 1608 are separated spatially by the openings 1610. This development may be achieved using an appropriate developer solution selected based on the compositions of the solubility-shifted region 1605, the first resist 1603, and the second resist 1608.

According to various embodiments, a two-step development process may be employed. First, a developer for the second resist 1608 may be used to remove any overburden. A second development step may then be performed using a second developer selected to remove the solubility-shifted region 1606 and any remnants of the solubility-shifting agent 1605. In certain such embodiments, the second developer may be a solvent of the solubility-shifting agent 1605. In other embodiments, the developer may be an aqueous base solution, such as aqueous tetramethylammonium hydroxide. These development steps may be performed according to any desired method, such as a dip, puddle, spray, or dynamic dispense method, in various embodiments.

A width of the openings 1610 corresponds to the thickness of the solubility-shifted region 1606 that was developed away (along with any remnant thickness of the solubility-shifting agent 1605). The width of the openings 1610 may be between 5 nm and 60 nm, according to embodiments. In some embodiments, the openings 1610 may have width between 5 nm and 30 nm, or between 5 nm and 15 nm.

After development, and in various embodiments, a height of the second resist 1608 over the substrate 1602 may differ from a height of the relief pattern 1604, creating a non-planar top surface across the structure. According to embodiments, a height difference or overhang of the second resist 1608 may be controlled or eliminated by tuning the composition or an initially applied thickness of the second resist 1608, or as otherwise described with reference to FIG. 1E.

The relief pattern 1604 and the second resist 1608 may be used together as a combined etch mask for forming features in the substrate 1602. FIG. 16F depicts a partially etched workpiece in which etched features 1612 extend below an original surface of the substrate 1602, with intact portions of the substrate 1602 covered by the relief pattern 1604 and the second resist 1608. Etching may be carried out using various techniques described above with reference to FIG. 1F, according to embodiments.

After the etching process is complete, any remaining portions of the first resist 1603 and the second resist 1608 may be removed using appropriate stripping processes, leaving the substrate 1602 with the etched features 1612. These etched features 1612 may form semiconductor device structures, such as contacts, vias, trenches, or other circuit elements, in various embodiments. In some embodiments, the etched features 1612 may be cuts in existing structures (such as lines) patterned on the substrate 1602.

FIGS. 17A-17E illustrate parts of an alternate process flow comprising the substrate 1602, the first resist 1603, and the second resist 1608, as well as a solubility-shifting agent 1705 that targets the first resist 1603, according to various embodiments. Diffusion of the solubility-shifting agent 1705 into the first resist 1603 results in the formation of a solubility-shifted region 1706 that has increased solubility in the developer. The relief pattern 1704 may have a larger critical dimension than the relief pattern 1604 while yielding a similar combined etch mask, because the relief pattern 1704 will be dimensionally reduced by the size of the solubility-shifted region.

In FIG. 17A, the relief pattern 1704 is provided on the substrate 1602 and coated by the solubility-shifting agent 1705. Diffusion of fluorine-free acid generator (or acid produced by activation of the fluorine-free acid generator) from the solubility-shifting agent 1705 into the first resist 1603 forms the solubility-shifted region 1706, along similar lines as described above, and in various embodiments. Then, the solubility-shifting agent 1705 is either absorbed into the first resist 1603 or rinsed away by a suitable method (such as dip, puddle, spray, or dynamic dispense), producing a workpiece like that depicted in FIG. 17B, according to embodiments.

In FIG. 17C, and according to embodiments, the second resist 1608 is formed (coated or deposited) over the relief pattern 1704, filling any gaps, such that the solubility-shifted region 1706 is disposed between the first resist 1603 and the second resist 1608. Development of any overburden of the second resist 1608 and the solubility-shifted region 1706 may then be performed, whether in a single step using a developer in which the second resist 1608 is only slightly soluble, as described above, or in a two-step process comprising different developers, according to the respective embodiments.

The result of the development may be a workpiece like that depicted in FIG. 17D, in which openings 1710 are disposed between the relief pattern 1704 and the second resist 1708, such that the relief pattern 1704 and the second resist 1708 are separated spatially by the openings 1710.

A width of the openings 1710 corresponds to the thickness of the solubility-shifted region 1706 that was developed away. The width of the openings 1710 may be between 5 nm and 60 nm, according to embodiments. In some embodiments, the openings 1710 may have width between 5 nm and 30 nm, or between 5 nm and 15 nm. Any height difference between the second resist 1608 and the relief pattern 1704, or any overhang of the second resist 1608, may be controlled or eliminated by tuning the composition or an initially applied thickness of the second resist 1608, or as otherwise described with reference to FIGS. 1E and 16E.

The relief pattern 1704 and the second resist 1608 may be used together as a combined etch mask for forming features in the substrate 1602. FIG. 17E depicts a partially etched workpiece in which etched features 1712 extend below an original surface of the substrate 1602, with intact portions of the substrate 1602 covered by the relief pattern 1704 and the second resist 1608. Etching may be carried out using various techniques described above with reference to FIG. 1F or FIG. 16F, according to embodiments.

Stripping of any remaining portions of the first resist 1603 and the second resist 1608 may then be performed, as described above, leaving the substrate 1602 with the etched features 1712. These etched features 1712 may form semiconductor device structures, such as contacts, vias, trenches, or other circuit elements, in various embodiments. In some embodiments, the etched features 1712 may be cuts in existing structures (such as lines) patterned on the substrate 1602.

The process flows described with reference to FIGS. 1A-1F may represent various embodiments of a more general method of patterning a substrate, as illustrated by a flow chart in FIG. 18.

In block 1801, a first relief pattern is provided on a substrate, wherein the first relief pattern comprises a first resist. Next, in block 1802, the first relief pattern is coated with an overcoat layer comprising a fluorine-free acid generator. According to embodiments, the overcoat layer may have a composition such as overcoat composition 20 of FIG. 2A, and the fluorine-free acid generator may have a composition such as that of the fluorine-free acid generator 22 of FIG. 2A or 2B, corresponding to various combinations of Schemes (Si)-(S10) and the example structures provided in FIGS. 5-13.

Then, in block 1803, the fluorine-free acid generator is activated to form a plurality of acid species within the overcoat layer. See, for example, the acid species 108 depicted in FIG. 1C. In block 1804, a portion of the plurality of acid species is diffused into the first resist to form a solubility-shifted region of the first resist. See, for example, the solubility-shifted region 105 in FIG. 1D.

In block 1805, the solubility-shifted region of the first resist is developed to form a plurality of openings disposed between the first relief pattern and the overcoat layer, resulting in a workpiece (for example) like that in FIG. 1E. Then, in block 1806, the substrate is etched using the first relief pattern and the overcoat layer as a combined etch mask. At an intermediate stage in the etching, the workpiece may (for example) appear like that in FIG. 1F.

The process flows described with reference to FIGS. 16A-16F and FIGS. 17A-17F may represent various embodiments of a more general method of patterning a substrate, as illustrated by a flow chart in FIG. 19.

In block 1901, a first relief pattern is provided on a substrate, wherein the first relief pattern comprises a first resist. Next, in block 1902, the first relief pattern is coated with a solubility-shifting agent comprising a fluorine-free acid generator. (See, for example, FIG. 16B or FIG. 17A.) The fluorine-free acid generator comprises a five-membered ring substituted with one or more electron-withdrawing groups.

According to various embodiments, the solubility-shifting agent may have a composition similar to the overcoat composition 20 of FIG. 2A, or it may have a different composition (omitting the base quencher 204, for example) tailored to shift the solubility of a target resist. In some embodiments, the target resist may be the first resist or a second resist to be formed in block 1903. The fluorine-free acid generator of the solubility-shifting composition may have a composition such as that of the fluorine-free acid generator 22 of FIG. 2A or 2B, corresponding to various combinations of Schemes (S1)-(S10) and the example structures provided in FIGS. 5-13, according to embodiments.

In block 1903, a second resist is formed over the first relief pattern, as (for example) in FIG. 16C. Next, in block 1904, a solubility-shifted region is formed, disposed between the first resist and the second resist. See, for example, FIG. 16D.

In some embodiments, such as those illustrated by FIGS. 17A-17C, block 1903 and block 1904 may be reordered and also preceded by an additional step. A solubility-shifted region may be formed over the first resist, as (for example) in FIG. 17B. Next, in block 1903, a second resist is formed over the first relief pattern, as (for example) in FIG. 17C. Formation of the second resist also completes block 1904, forming the solubility-shifted region disposed between the first resist and the second resist.

In various embodiments of block 1904, forming the solubility-shifted region may comprise activating the fluorine-free acid generator to form a plurality of acid species within the solubility-shifting agent. Forming the solubility-shifted region may further comprise diffusing a portion of the plurality of acid species into either the first resist or the second resist, in respective embodiments.

In block 1905, the solubility-shifted region is developed, as illustrated (for example) in FIG. 16E or FIG. 17D. Then, in block 1906, the substrate is etched using the first relief pattern and the overcoat layer as a combined etch mask. At an intermediate stage in the etching, the workpiece may (for example) appear like that in FIG. 16F or FIG. 17E.

Example embodiments of the invention are described below. Other embodiments can also be understood from the entirety of the specification as well as the claims filed herein.

Example 1. An overcoat composition includes a polymer, a fluorine-free acid generator, a base quencher, and an organic solvent. The fluorine-free acid generator includes a five-membered aromatic ring substituted with one or more electron-withdrawing groups.

Example 2. The overcoat composition of example 1, where the fluorine-free acid generator further includes a cation and an anion, where the five-membered aromatic ring is cyclopentadienide, where the anion is represented by one or more of Schemes (Si) to (S3), where E¹-E⁵ are separately selected electron-withdrawing groups; R¹-R⁵ are separately selected organic substituent groups; L¹-L³ are separately selected linkers; n1 is a positive integer; and n2-n5 and m1-m5 are non-negative integers.

Example 3. The overcoat composition of example 2, where E¹-E⁵ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR⁶, —SR⁷, —NO₂, —CN, —C(O)R⁸, —C(O)OR⁹, —C(O)NR¹⁰R¹¹, —S(O)₂OR¹², —S(O)R¹³, —S(O)₂R¹⁴, —OS(O)₂R¹⁵, or a combination thereof; R⁶-R¹² are each independently hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl; R¹³-R¹⁵ are each independently substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl; R¹-R⁵ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; L¹-L³ are each independently a hydrogen, a single bond, or a divalent linking group, or any of the above groups as defined for R¹, R², R³, R⁴, and R⁵ or E¹, E², E³, E⁴, and E⁵; n1 is an integer from 1 to 4; n2 is an integer from 0 to 4, and n3 is an integer from 0 to 2, provided that at least one of n2 and n3 is not 0; n4 and n5 are each independently an integer from 0 to 4, provided that at least one of n4 and n5 is not 0; m1 is an integer from 0 to 3; m2 is an integer from 0 to 4, and m3 is an integer from 0 to 2; and m4 and m5 are each independently an integer from 0 to 4.

Example 4. The overcoat composition of one of examples 2 or 3, where at least one of R¹, R², R³, R⁴, and R⁵ further includes one or both of a divalent linking group or a polymerizable group.

Example 5. The overcoat composition of one of examples 2 to 4, where the cation is a sulfonium cation or an iodonium cation.

Example 6. The overcoat composition of one of examples 2 to 4, where the cation is represented by a formula (BH)⁺, where B is a base including nitrogen and (BH)⁺ has pKₐ between 0 and 6.

Example 7. The overcoat composition of one of examples 2 to 4, where the cation is a proton (H⁺).

Example 8. The overcoat composition of example 1, where the fluorine-free acid generator further includes a cation and an anion; where the five-membered aromatic ring is pyrrole with or without N-substitution, furan, or thiophene; where the anion is represented by one or more of Schemes (S4) to (S5), where X¹ and X² are separately selected heteroatoms; Y¹ and Y² are separately selected atoms; Z¹ and Z² are separately selected pendant groups; E⁶ and E⁷ are separately selected electron-withdrawing groups; R¹⁶ and R¹⁷ are separately selected organic substituent groups; n6, m6, and m7 are non-negative integers; and n7 is a positive integer.

Example 9. The overcoat composition of example 8, where X¹ and X² are separately selected from a group consisting of S, O, and NR, where R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; Y¹ and Y² are separately selected from a group consisting of C and N; Z¹ and Z² are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁶ and E⁷, provided that when Y¹ or Y² is N, Z¹ or Z² is respectively not present; E⁶ and E⁷ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR¹⁸, —SR¹⁹, —NO₂, —CN, —C(O)R²⁰, —C(O)OR²¹, —C(O)NR²²R²³, —S(O)₂OR²⁴, —S(O)R²⁵, —S(O)₂R²⁶, —OS(O)₂R²⁷, or a combination thereof; R¹⁶-R²⁷ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; n6 is an integer from 0 to 2; n7 is an integer from 1 to 4; m6 is an integer from 0 to 2; and m7 is an integer from 0 to 2.

Example 10. The overcoat composition of one of examples 8 or 9, where at least one of R¹⁶ and R¹⁷ further comprises one or both of a divalent linking group or a polymerizable group.

Example 11. The overcoat composition of one of examples 8 to 10, where the cation is a sulfonium cation or an iodonium cation.

Example 12. The overcoat composition of one of examples 8 to 10, where the cation is represented by a formula (BH)⁺, where B is a base including nitrogen and (BH)⁺ has pKₐ between 0 and 6.

Example 13. The overcoat composition of one of examples 8 to 10, where the cation is a proton (H⁺).

Example 14. The overcoat composition of example 1, where the five-membered aromatic ring is pyrrole with or without N-substitution, furan, or thiophene, and where the fluorine-free acid generator is represented by one or more of Schemes (S9) to (S10), where X³ and X⁴ are separately selected heteroatoms; Y³ and Y⁴ are separately selected atoms; Z³ and Z⁴ are separately selected pendant groups; E⁸ and E⁹ are separately selected electron-withdrawing groups; R³³-R³⁶ are separately selected organic substituent groups; L⁴ and L⁵ are separately selected linkers; n8, m8, and m9 are non-negative integers; and n9 is a positive integer.

Example 15. The overcoat composition of example 14, where X³ and X⁴ are separately selected from a group consisting of S, O and NR, where R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; Y³ and Y⁴ are separately selected from a group consisting of C and N; Z³ and Z⁴ are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁸ and E⁹, provided that when Y³ or Y⁴ is N, Z³ or Z⁴ is respectively not present; E⁸ and E⁹ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR³⁷, —SR³⁸, —NO₂, —CN, —C(O)R³⁹, —C(O)OR⁴⁰, —C(O)NR⁴¹R⁴², —S(O)₂OR⁴³, —S(O)R⁴⁴, —S(O)₂R⁴⁵, —OS(O)₂R⁴⁶, or a combination thereof; R³³-R⁴⁶ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; L⁴ and L⁵ are each independently a single bond or a divalent linking group; n8 is an integer from 0 to 2; n9 is an integer from 1 to 4; m8 is an integer from 0 to 2; and m9 is an integer from 0 to 4.

Example 16. The overcoat composition of one of examples 14 or 15, where at least one of R³³-R³⁶ further comprises one or both of a divalent linking group or a polymerizable group.

Example 17. The overcoat composition of one of examples 1 to 16, where the polymer includes polymerized units of Scheme (P1), Scheme (P2), or Scheme (P3), where each X is independently a halogen atom; Q is a single bond or a divalent linking group; R^{a} is hydrogen, a halogen atom, substituted or unsubstituted C₁-C₁₂ alkyl, or substituted or unsubstituted C₁-C₁₂ haloalkyl; R^{b} is hydrogen, C₁-C₃ alkyl, or C₁-C₃ haloalkyl; W is O or NR, where R represents hydrogen or C₁-C₆ alkyl; R^{c} is hydrogen, a halogen atom, C₁-C₃ alkyl or C₁-C₃ haloalkyl; R^{d} is substituted or unsubstituted C₁-C₂₀ alkyl or substituted or unsubstituted C₁-C₂₀ heteroalkyl; and k is an integer from 0 to 4.

Example 18. The overcoat composition of one of examples 1 to 17, where the base quencher comprises tetramethylammonium hydroxide, tetrabutylammonium lactate, 1,8-diazabicyclo[5.4.0]undec-7-ene, 1-piperidineethanol, triethanolamine, 1-tert-butoxycarbonyl-4-hydroxypiperidine, tert-butyl N-[2-hydroxy-1,1-bis(hydroxymethyl)-ethyl]carbamate, triphenylsulfonium phenolate, triphenylsulfonium 10-camphorsulfonate, or phenyldibenzothiophenium phenolate.

Example 19. The overcoat composition of one of examples 1 to 18, where the organic solvent comprises diisoamyl ether, anisole, 1-butanol, methyl isobutyl carbinol, n-butyl acetate, isobutyl isobutyrate, γ-butyrolactone, n-decane, 2-heptanone, or a combination thereof.

Example 20. A method of patterning a substrate includes providing a first relief pattern on the substrate, where the first relief pattern includes a first resist; coating the first relief pattern with an overcoat layer including a fluorine-free acid generator; activating the fluorine-free acid generator to form a plurality of acid species within the overcoat layer; diffusing a portion of the plurality of acid species into the first resist to form a solubility-shifted region of the first resist; developing the solubility-shifted region of the first resist; and etching the substrate using the first relief pattern and the overcoat layer as a combined etch mask.

Example 21. The method of example 20, where the fluorine-free acid generator further includes a cation and an anion, where the five-membered aromatic ring is cyclopentadienide, where the anion is represented by one or more of Schemes (Si) to (S3), where E¹-E⁵ are separately selected electron-withdrawing groups; R¹-R⁵ are separately selected organic substituent groups; L¹-L³ are separately selected linkers; n1 is a positive integer; and n2-n5 and m1-m5 are non-negative integers.

Example 22. The method of example 21, where E¹-E⁵ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR⁶, —SR⁷, —NO₂, —CN, —C(O)R⁸, —C(O)OR⁹, —C(O)NR¹⁰OR¹¹, —S(O)₂OR¹², —S(O)R¹³, —S(O)₂R¹⁴, —OS(O)₂R¹⁵, or a combination thereof; R⁶-R¹² are each independently hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl; R¹³-R¹⁵ are each independently substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl; R¹-R⁵ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; L-L³ are each independently a hydrogen, a single bond, or a divalent linking group, or any of the above groups as defined for R¹, R², R³, R⁴, and R⁵ or E¹, E², E³, E⁴, and E⁵; n1 is an integer from 1 to 4; n2 is an integer from 0 to 4, and n3 is an integer from 0 to 2, provided that at least one of n2 and n3 is not 0; n4 and n5 are each independently an integer from 0 to 4, provided that at least one of n4 and n5 is not 0; m1 is an integer from 0 to 3; m2 is an integer from 0 to 4, and m3 is an integer from 0 to 2; and m4 and m5 are each independently an integer from 0 to 4.

Example 23. The method of one of examples 21 or 22, where at least one of R¹, R², R³, R⁴, and R⁵ further comprises one or both of a divalent linking group or a polymerizable group.

Example 24. The method of one of examples 21 to 23, where the cation is a sulfonium cation or an iodonium cation.

Example 25. The method of one of examples 21 to 23, where the cation is represented by a formula (BH)⁺, where B is a base including nitrogen and (BH)⁺ has pKₐ between 0 and 6.

Example 26. The method of one of examples 21 to 23, where the cation is a proton (H⁺).

Example 27. The method of example 20, where the fluorine-free acid generator includes a cation and an anion represented by one or more of Schemes (S4) to (S5), where X¹ and X² are separately selected heteroatoms; Y¹ and Y² are separately selected atoms; Z¹ and Z² are separately selected pendant groups; E⁶ and E⁷ are separately selected electron-withdrawing groups; R¹⁶ and R¹⁷ are separately selected organic substituent groups; n6, m6, and m7 are non-negative integers; and n7 is a positive integer.

Example 28. The method of example 27, where X¹ and X² are separately selected from a group consisting of S, O, and NR, where R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; Y¹ and Y² are separately selected from a group consisting of C and N; Z¹ and Z² are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁶ and E⁷, provided that when Y¹ or Y² is N, Z¹ or Z² is respectively not present; E⁶ and E⁷ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR¹⁸, —SR¹⁹, —NO₂, —CN, —C(O)R²⁰, —C(O)OR²¹, —C(O)NR²²R²³, —S(O)₂OR²⁴, —S(O)R², —S(O)₂R²⁶, —OS(O)₂R²⁷, or a combination thereof; R¹⁶-R²⁷ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; n6 is an integer from 0 to 2; n7 is an integer from 1 to 4; m6 is an integer from 0 to 2; and m7 is an integer from 0 to 2.

Example 29. The method of one of examples 27 or 28, where at least one of R¹⁶ and R¹⁷ further comprises one or both of a divalent linking group or a polymerizable group.

Example 30. The method of example 20, where the fluorine-free acid generator is represented by one or more of Schemes (S9) to (S10), where X³ and X⁴ are separately selected heteroatoms; Y³ and Y⁴ are separately selected atoms; Z³ and Z⁴ are separately selected pendant groups; E⁸ and E⁹ are separately selected electron-withdrawing groups; R³³-R⁶ are separately selected organic substituent groups; L⁴ and L⁵ are separately selected linkers; n8, m8, and m9 are non-negative integers; and n9 is a positive integer.

Example 31. The method of example 30, where X³ and X⁴ are separately selected from a group consisting of S, O and NR, where R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; Y³ and Y⁴ are separately selected from a group consisting of C and N; Z³ and Z⁴ are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁸ and E⁹, provided that when Y³ or Y⁴ is N, Z³ or Z⁴ is respectively not present; E⁸ and E⁹ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR³⁷, —SR³⁸, —NO₂, —CN, —C(O)R³⁹, —C(O)OR⁴⁰, —C(O)NR⁴¹R⁴², —S(O)₂OR⁴³, —S(O)R⁴⁴, —S(O)₂R⁴⁵, —OS(O)₂R⁴⁶, or a combination thereof; R³³-R⁴⁶ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; L⁴ and L⁵ are each independently a single bond or a divalent linking group; n8 is an integer from 0 to 2; n9 is an integer from 1 to 4; m8 is an integer from 0 to 2; and m9 is an integer from 0 to 4.

Example 32. The method of one of examples 30 or 31, where at least one of R³³-R³⁶ further comprises one or both of a divalent linking group or a polymerizable group.

Example 33. A method of patterning a substrate includes providing a first relief pattern on the substrate, where the first relief pattern includes a first resist; coating the first relief pattern with a solubility-shifting agent including a fluorine-free acid generator, the fluorine-free acid generator including a five-membered aromatic ring substituted with one or more electron-withdrawing groups; forming a second resist over the first relief pattern; forming a solubility-shifted region disposed between the first resist and the second resist; developing the solubility-shifted region; and etching the substrate using the first relief pattern and the second resist as a combined etch mask.

Example 34. The method of example 33, where the fluorine-free acid generator further includes a cation and an anion including the five-membered aromatic ring, where the five-membered aromatic ring is cyclopentadienide, where the anion is represented by one or more of Schemes (S1) to (S3), where E¹-E⁵ are separately selected electron-withdrawing groups; R¹-R⁵ are separately selected organic substituent groups; L¹-L³ are separately selected linkers; n1 is a positive integer; and n2-n5 and m1-m5 are non-negative integers.

Example 35. The method of example 34, where E¹-E⁵ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR⁶, —SR⁷, —NO₂, —CN, —C(O)R⁸, —C(O)OR⁹, —C(O)NR¹⁰R¹¹, —S(O)₂OR¹², —S(O)R¹³, —S(O)₂R¹⁴, —OS(O)₂R¹⁵, or a combination thereof; R⁶-R¹² are each independently hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl; R¹³-R¹⁵ are each independently substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl; R¹-R⁵ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; L-L³ are each independently a hydrogen, a single bond, or a divalent linking group, or any of the above groups as defined for R¹, R², R³, R⁴, and R⁵ or E¹, E², E³, E⁴, and E⁵; n1 is an integer from 1 to 4; n2 is an integer from 0 to 4, and n3 is an integer from 0 to 2, provided that at least one of n2 and n3 is not 0; n4 and n5 are each independently an integer from 0 to 4, provided that at least one of n4 and n5 is not 0; m1 is an integer from 0 to 3; m2 is an integer from 0 to 4, and m3 is an integer from 0 to 2; and m4 and m5 are each independently an integer from 0 to 4.

Example 36. The method of one of examples 34 or 35, where at least one of R¹, R², R³, R⁴, and R⁵ further comprises one or both of a divalent linking group or a polymerizable group.

Example 37. The method of one of examples 34 to 36, where the cation is a sulfonium cation or an iodonium cation.

Example 38. The method of one of examples 34 to 36, where the cation is represented by a formula (BH)⁺, where B is a base comprising nitrogen and (BH)⁺ has pKₐ between 0 and 6.

Example 39. The method of one of examples 34 to 36, where the cation is a proton (H⁺).

Example 40. The method of example 33, where the fluorine-free acid generator further includes a cation and an anion including the five-membered aromatic ring; where the five-membered aromatic ring is pyrrole with or without N-substitution, furan, or thiophene; where the anion is represented by one or more of Schemes (S4) to (S5), where X¹ and X² are separately selected heteroatoms; Y¹ and Y² are separately selected atoms; Z¹ and Z² are separately selected pendant groups; E⁶ and E⁷ are separately selected electron-withdrawing groups; R¹⁶ and R¹⁷ are separately selected organic substituent groups; n6, m6, and m7 are non-negative integers; and n7 is a positive integer.

Example 41. The method of example 40, where X¹ and X² are separately selected from a group consisting of S, O, and NR, where R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; Y¹ and Y² are separately selected from a group consisting of C and N; Z¹ and Z² are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁶ and E⁷, provided that when Y¹ or Y² is N, Z¹ or Z² is respectively not present; E⁶ and E⁷ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR¹⁸, —SR¹⁹, —NO₂, —CN, —C(O)R²⁰, —C(O)OR²¹, —C(O)NR²²R²³, —S(O)₂OR²⁴, —S(O)R², —S(O)₂R²⁶, —OS(O)₂R²⁷, or a combination thereof; R¹⁶-R²⁷ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; n6 is an integer from 0 to 2; n7 is an integer from 1 to 4; m6 is an integer from 0 to 2; and m7 is an integer from 0 to 2.

Example 42. The method of one of examples 40 or 41, where at least one of R¹⁶ and R¹⁷ further comprises one or both of a divalent linking group or a polymerizable group.

Example 43. The method of example 33, where the five-membered aromatic ring is pyrrole with or without N-substitution, furan, or thiophene, and where the fluorine-free acid generator is represented by one or more of Schemes (S9) to (S10), where X³ and X⁴ are separately selected heteroatoms; Y³ and Y⁴ are separately selected atoms; Z³ and Z⁴ are separately selected pendant groups; E⁸ and E⁹ are separately selected electron-withdrawing groups; R³³-R³⁶ are separately selected organic substituent groups; L⁴ and L⁵ are separately selected linkers; n8, m8, and m9 are non-negative integers; and n9 is a positive integer.

Example 44. The method of one of example 43, where X³ and X⁴ are separately selected from a group consisting of S, O and NR, where R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; Y³ and Y⁴ are separately selected from a group consisting of C and N; Z³ and Z⁴ are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁸ and E⁹, provided that when Y³ or Y⁴ is N, Z³ or Z⁴ is respectively not present; E⁸ and E⁹ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR³⁷, —SR³⁸, —NO₂, —CN, —C(O)R³⁹, —C(O)OR⁴⁰, —C(O)NR⁴¹R⁴², —S(O)₂OR⁴³, —S(O)R⁴⁴, —S(O)₂R⁴⁵, —OS(O)₂R⁴⁶, or a combination thereof; R³³-R⁴⁶ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl; L⁴ and L⁵ are each independently a single bond or a divalent linking group; n8 is an integer from 0 to 2; n9 is an integer from 1 to 4; m8 is an integer from 0 to 2; and m9 is an integer from 0 to 4.

Example 45. The method of one of examples 43 or 44, where at least one of R³³-R³ further comprises one or both of a divalent linking group or a polymerizable group.

Example 46. The method of one of examples 33 to 45, where forming the solubility-shifted region includes activating the fluorine-free acid generator to form a plurality of acid species within the solubility-shifting agent, and diffusing a portion of the plurality of acid species into the second resist.

Example 47. The method of one of examples 33 to 46, where forming the solubility-shifted region includes activating the fluorine-free acid generator to form a plurality of acid species within the solubility-shifting agent, and diffusing a portion of the plurality of acid species into the first resist.

While this invention has been described with reference to illustrative embodiments, this description is not intended to be construed in a limiting sense. Various modifications and combinations of the illustrative embodiments, e.g., of FIGS. 1-19, as well as other embodiments of the invention, will be apparent to persons skilled in the art upon reference to the description. It is therefore intended that the appended claims encompass any such modifications or embodiments.

What is claimed is:

1. An overcoat composition comprising:
a polymer;
a fluorine-free acid generator comprising a five-membered aromatic ring substituted with one or more electron-withdrawing groups;
a base quencher; and
an organic solvent.

2. The overcoat composition of claim 1, wherein the fluorine-free acid generator further comprises:
a cation; and
an anion, wherein the five-membered aromatic ring is cyclopentadienide, wherein the anion is represented by one or more of Schemes (S1) to (S3): 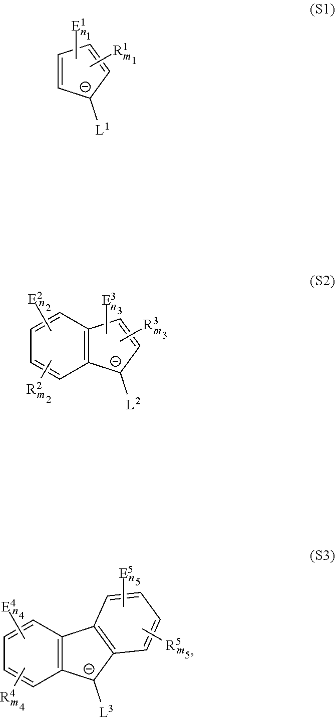
wherein
E¹-E⁵ are separately selected electron-withdrawing groups;
R¹-R⁵ are separately selected organic substituent groups;
L¹-L³ are separately selected linkers;
n1 is a positive integer; and
n2-n5 and m1-m5 are non-negative integers.

3. The overcoat composition of claim 2, wherein
E¹-E⁵ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR⁶, —SR⁷, —NO₂, —CN, —C(O)R⁸, —C(O)OR⁹, —C(O)NR¹⁰R¹¹, —S(O)₂OR¹², —S(O)R¹³, —S(O)₂R¹⁴, —OS(O)₂R¹⁵, or a combination thereof;
R⁶-R¹² are each independently hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl;
R¹³-R¹⁵ are each independently substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl;
R¹-R⁵ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl;
L¹-L³ are each independently a hydrogen, a single bond, or a divalent linking group, or any of the above groups as defined for R¹, R², R³, R⁴, and R⁵ or E¹, E², E³, E⁴, and E⁵;
n1 is an integer from 1 to 4;
n2 is an integer from 0 to 4, and n3 is an integer from 0 to 2, provided that at least one of n2 and n3 is not 0;
n4 and n5 are each independently an integer from 0 to 4, provided that at least one of n4 and n5 is not 0;
m1 is an integer from 0 to 3;
m2 is an integer from 0 to 4, and m3 is an integer from 0 to 2; and
m4 and m5 are each independently an integer from 0 to 4.

4. The overcoat composition of claim 2, wherein the cation is a sulfonium cation or an iodonium cation.

5. The overcoat composition of claim 2, wherein the cation is represented by a formula (BH)⁺, wherein B is a base comprising nitrogen and (BH)⁺ has pKₐ between 0 and 6.

6. The overcoat composition of claim 2, wherein the cation is a proton (H⁺).

7. The overcoat composition of claim 1, wherein the fluorine-free acid generator further comprises:
a cation; and
an anion, wherein the five-membered aromatic ring is pyrrole with or without N-substitution, furan, or thiophene, wherein the anion is represented by one or more of Schemes (S4) to (S5): 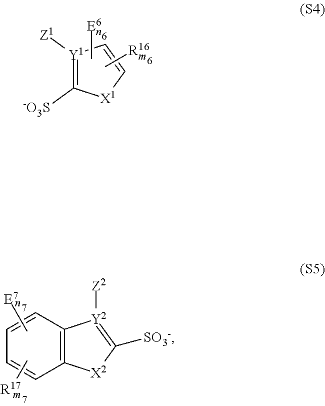
wherein
X¹ and X² are separately selected heteroatoms;
Y¹ and Y² are separately selected atoms;
Z¹ and Z² are separately selected pendant groups;
E⁶ and E⁷ are separately selected electron-withdrawing groups;
R¹⁶ and R¹⁷ are separately selected organic substituent groups;
n6, m6, and m7 are non-negative integers; and
n7 is a positive integer.

8. The overcoat composition of claim 7, wherein
X¹ and X² are separately selected from a group consisting of S, O, and NR, wherein R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl;
Y¹ and Y² are separately selected from a group consisting of C and N;
Z¹ and Z² are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁶ and E⁷, provided that when Y¹ or Y² is N, Z¹ or Z² is respectively not present;
E⁶ and E⁷ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR¹⁸, —SR⁹, —NO₂, —CN, —C(O)R²⁰, —C(O)OR²¹, —C(O)NR²²R²³, —S(O)₂OR²⁴, —S(O)R₂, —S(O)₂R²⁶, —OS(O)₂R²⁷, or a combination thereof;
R¹⁶-R²⁷ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl;
n6 is an integer from 0 to 2;
n7 is an integer from 1 to 4;
m6 is an integer from 0 to 2; and
m7 is an integer from 0 to 2.

9. The overcoat composition of claim 7, wherein the cation is a sulfonium cation or an iodonium cation.

10. The overcoat composition of claim 7, wherein the cation is represented by a formula (BH)⁺, wherein B is a base comprising nitrogen and (BH)⁺ has pKₐ between 0 and 6.

11. The overcoat composition of claim 7, wherein the cation is a proton (H⁺).

12. The overcoat composition of claim 1, wherein the five-membered aromatic ring is pyrrole with or without N-substitution, furan, or thiophene, and wherein the fluorine-free acid generator is represented by one or more of Schemes (S9) to (S10): 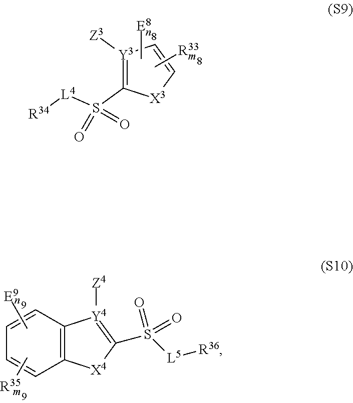
wherein
X³ and X⁴ are separately selected heteroatoms;
Y³ and Y⁴ are separately selected atoms;
Z³ and Z⁴ are separately selected pendant groups;
E⁸ and E⁹ are separately selected electron-withdrawing groups;
R³³-R³⁶ are separately selected organic substituent groups;
L⁴ and L⁵ are separately selected linkers;
n8, m8, and m9 are non-negative integers; and
n9 is a positive integer.

13. The overcoat composition of claim 12, wherein
X³ and X⁴ are separately selected from a group consisting of S, O and NR, wherein R is hydrogen, substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl;
Y³ and Y⁴ are separately selected from a group consisting of C and N;
Z³ and Z⁴ are separately selected from a group consisting of hydrogen, substituted or unsubstituted C₁-C₂₀ alkyl, substituted or unsubstituted C₃-C₂₀ cycloalkyl, substituted or unsubstituted C₃-C₂₀ heterocycloalkyl, substituted or unsubstituted C₆-C₂₀ aryl, substituted or unsubstituted C₇-C₂₀ alkylaryl, substituted or unsubstituted C₇-C₂₀ arylalkyl, substituted or unsubstituted C₃-C₂₀ heteroaryl, substituted or unsubstituted C₄-C₂₀ alkylheteroaryl, or substituted or unsubstituted C₄-C₂₀ heteroarylalkyl, or any of the below groups as defined for E⁸ and E⁹, provided that when Y³ or Y⁴ is N, Z³ or Z⁴ is respectively not present;
E⁸ and E⁹ are each independently halogen, substituted or unsubstituted C₁-C₂₀ haloalkyl, substituted or unsubstituted C₆-C₂₀ aryl, substituted or unsubstituted C₃-C₂₀ heteroaryl, —OR³⁷, —SR³⁸, —NO₂, —CN, —C(O)R³⁹, —C(O)OR⁴⁰, —C(O)NR⁴¹R⁴², —S(O)₂OR⁴³, —S(O)R⁴⁴, —S(O)₂R⁴⁵, —OS(O)₂R⁴⁶, or a combination thereof;
R³³-R⁴⁶ are each independently substituted or unsubstituted C₁-C₃₀ alkyl, substituted or unsubstituted C₁-C₃₀ heteroalkyl, substituted or unsubstituted C₄-C₃₀ cycloalkyl, substituted or unsubstituted C₃-C₂₀ heterocycloalkyl, substituted or unsubstituted C₆-C₃₀ aryl, substituted or unsubstituted C₇-C₃₀ arylalkyl, substituted or unsubstituted C₇-C₃₀ alkylaryl, substituted or unsubstituted C₃-C₃₀ heteroaryl, substituted or unsubstituted C₄-C₃₀ heteroarylalkyl, or substituted or unsubstituted C₄-C₃₀ alkylheteroaryl;
L⁴ and L⁵ are each independently a single bond or a divalent linking group;
n8 is an integer from 0 to 2;
n9 is an integer from 1 to 4;
m8 is an integer from 0 to 2; and
m9 is an integer from 0 to 4.

14. The overcoat composition of claim 1, wherein the polymer comprises polymerized units of Scheme (P1), Scheme (P2), or Scheme (P3): 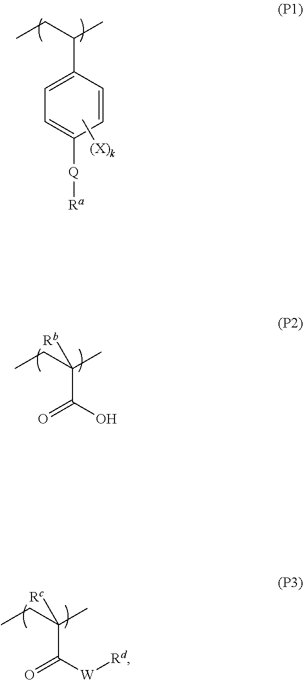
wherein
each X is independently a halogen atom;
Q is a single bond or a divalent linking group;
R^{a} is hydrogen, a halogen atom, substituted or unsubstituted C₁-C₁₂ alkyl, or substituted or unsubstituted C₁-C₁₂ haloalkyl;
R^{b} is hydrogen, C₁-C₃ alkyl, or C₁-C₃ haloalkyl;
W is O or NR, wherein R represents hydrogen or C₁-C₆ alkyl;
R^{c} is hydrogen, a halogen atom, C₁-C₃ alkyl or C₁-C₃ haloalkyl;
R^{d} is substituted or unsubstituted C₁-C₂₀ alkyl or substituted or unsubstituted C₁-C₂₀ heteroalkyl; and
k is an integer from 0 to 4.

15. The overcoat composition of claim 1, wherein the base quencher comprises tetramethylammonium hydroxide, tetrabutylammonium lactate, 1,8-diazabicyclo[5.4.0]undec-7-ene, 1-piperidineethanol, triethanolamine, 1-tert-butoxycarbonyl-4-hydroxypiperidine, tert-butyl N-[2-hydroxy-1,1-bis(hydroxymethyl)-ethyl]carbamate, triphenylsulfonium phenolate, triphenylsulfonium 10-camphorsulfonate, or phenyldibenzothiophenium phenolate.

16. The overcoat composition of claim 1, wherein the organic solvent comprises diisoamyl ether, anisole, 1-butanol, methyl isobutyl carbinol, n-butyl acetate, isobutyl isobutyrate, γ-butyrolactone, n-decane, 2-heptanone, or a combination thereof.

17. A method of patterning a substrate, the method comprising:
providing a first relief pattern on the substrate, wherein the first relief pattern comprises a first resist;
coating the first relief pattern with an overcoat layer comprising a fluorine-free acid generator;
activating the fluorine-free acid generator to form a plurality of acid species within the overcoat layer;
diffusing a portion of the plurality of acid species into the first resist to form a solubility-shifted region of the first resist;
developing the solubility-shifted region of the first resist; and
etching the substrate using the first relief pattern and the overcoat layer as a combined etch mask.

18. The method of claim 17, wherein the fluorine-free acid generator comprises:
a cation; and
an anion represented by one or more of Schemes (S1) to (S3): 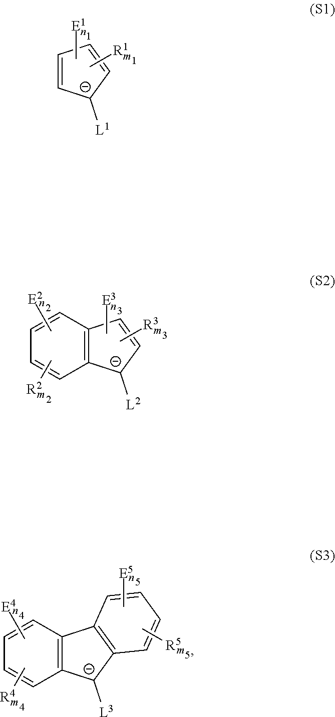
wherein
E¹-E⁵ are separately selected electron-withdrawing groups;
R¹-R⁵ are separately selected organic substituent groups;
L¹-L³ are separately selected linkers;
n1 is a positive integer; and
n2-n5 and m1-m5 are non-negative integers.

19. A method of patterning a substrate, the method comprising:
providing a first relief pattern on the substrate, wherein the first relief pattern comprises a first resist;
coating the first relief pattern with a solubility-shifting agent comprising a fluorine-free acid generator, the fluorine-free acid generator comprising a five-membered aromatic ring substituted with one or more electron-withdrawing groups;
forming a second resist over the first relief pattern;
forming a solubility-shifted region disposed between the first resist and the second resist;
developing the solubility-shifted region; and
etching the substrate using the first relief pattern and the second resist as a combined etch mask.

20. The method of claim 19, wherein the fluorine-free acid generator further comprises:
a cation; and
an anion comprising the five-membered aromatic ring, wherein the five-membered aromatic ring is cyclopentadienide, wherein the anion is represented by one or more of Schemes (S1) to (S3): 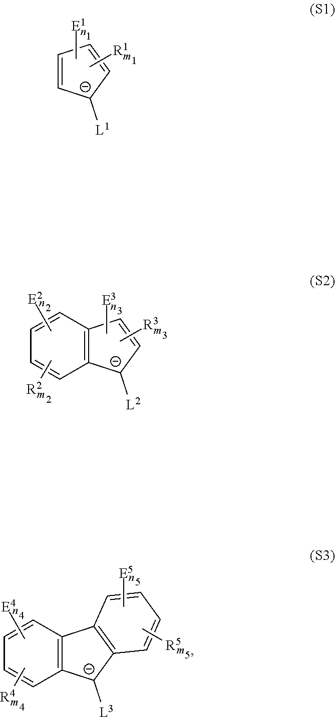
wherein
E¹-E⁵ are separately selected electron-withdrawing groups;
R¹-R⁵ are separately selected organic substituent groups;
L¹-L³ are separately selected linkers;
n1 is a positive integer; and
n2-n5 and m1-m5 are non-negative integers.
